(19) United States
(12) Patent Application Publication
(10) Pub. No.: US 2002/0105033 A1
(43) Pub. Date: Aug. 8, 2002

(54) THIN FILM TRANSISTOR HAVING LIGHTLY AND HEAVILY DOPED SOURCE/DRAIN REGIONS AND ITS MANUFACTURE

(76) Inventor: HONGYONG ZHANG, KAWASAKI-SHI (JP)

Correspondence Address: PATRICK G BURNS ESQ, GREER BURNS & CRAIN LTD, SEARS TOWER SUITE 8660, 233 S WACKER DRIVE, CHICAGO, IL, 60606

(21) Appl. No.: 09/468,489

(22) Filed: Dec. 20, 1999

(30) Foreign Application Priority Data
Mar. 19, 1999 (JP) 11-76801

(51) Int. Cl. H01L 27/12; H01L 21/00; H01L 31/0392

(52) U.S. Cl. 257/353; 257/354; 438/151

(57) ABSTRACT

A method of manufacturing thin film transistors on a substrate having an insulative surface comprises the steps of: (a) forming a plurality of island-shaped semiconductor layers on a substrate having an insulative surface; (b) implanting dopant into first regions at outsides of a region designated for a channel region in each of the semiconductor layers directly or through a thin insulation film whose thickness is equal to or less than 50 nm by ion implantation to form lightly doped regions; and (c) implanting dopant into regions at outsides of the first regions in each of the semiconductor layers directly or through the thin insulation film to form heavily doped source/drain regions whose impurity concentration is higher than that of the lightly doped regions.

This application is based on Japanese patent application HEI 11-76801, filed on Mar. 19, 1999, the entire contents of which are incorporated herein by reference.

### BACKGROUND OF THE INVENTION

a) Field of the Invention

The present invention relates to a thin film transistor, and more particularly to a thin film transistor formed on a substrate having an insulative surface, and a method of manufacturing the thin film transistor.

b) Description of the Related Art

Thin film transistors (TFTs) have been used in a liquid crystal display device or the like. A display portion of the liquid crystal display device comprises, for example, a liquid crystal sandwiched between a pair of glass substrates each having electrodes. Optical characteristics of the liquid crystal are controlled in accordance with voltages applied between the opposing electrodes, thus, images are displayed on the display portion.

In an active matrix type liquid crystal display device, a plurality of scanning lines and a plurality of signal lines which are intersecting each other are aligned on one glass substrate, and a pair of a switching transistor and a pixel electrode is arranged at each intersection. Each of the pairs forms a pixel, thus, matrix aligned pixels are formed in a display portion.

In each switching transistor, one current electrode (referred to as a drain electrode in this specification) is connected to the signal line, a gate electrode is connected to the scanning line, and the other current electrode (a source electrode) is connected to the pixel electrode. The source electrode may be called as the drain electrode and vice versa, because those names are given just for the sake of convenience.

The switching transistors are usually made of island-shaped silicon layers formed on the glass substrate. Generally, the glass substrate has heat resistance up to approximately 650 degrees Celsius, and actual heat resistance thereof in a practical use is up to 600 degrees Celsius. However, the glass substrate is preferably processed under a temperature of equal to or lower than 450 degrees Celsius, considering shrinkage of a large glass substrate. Because of such characteristics of the glass substrate, it is difficult to carry out chemical vapor deposition (CVD) or the like at a high temperature to deposit an excellent polysilicon layer directly onto the glass substrate. Therefore, amorphous silicon which can grow on the glass substrate under a low temperature is generally used for forming the switching transistors. And, thus formed amorphous silicon layer is patterned to be island-shaped semiconductor layers.

Since such the amorphous silicon layer has low carrier mobility, the performance of the completed TFTs using the amorphous silicon layer will not be excellent. Moreover, it is difficult to form peripheral circuits for driving the liquid crystal display device on the glass substrate on which the amorphous silicon TFTs are formed.

Of late, a technique for converting an amorphous silicon layer into a polysilicon layer has been established. The conversion according to this technique is realized by applying a laser beam to the amorphous silicon layer formed on a glass substrate. The polysilicon has greater carrier mobility than that of the amorphous silicon. Therefore, the polysilicon TFTs show excellent performance. Moreover, peripheral circuits can be formed on the same glass substrate forming a display portion.

It has been known that hot carriers injected into a gate insulation layer deteriorate the TFT performance. The hot carriers are generated when voltages are applied to the source and drain electrodes and the gate electrode by which a strong electric field appears near drain junction.

To manufacture a liquid crystal display device in which a peripheral circuit and a display unit are formed on the same glass substrate, each of the TFTs is required to have lightly doped drain (LDD) region which weaken the electric field.

Forming multiple TFTs on a large glass substrate is required to manufacture a liquid crystal display device. An ion implanting apparatus for doping is required to carry out ion implantation with a large current in order to form heavily doped source/drain regions on the large grass substrates. Also the LDD regions is preferably formed by the ion implanting apparatus. An apparatus for non-mass analyzed ion implantation which carries out the ion implantation without mass analysis has been developed as an ion implanting apparatus suitable for the above purposes.

FIGS. 2A and 2B show the structures of two types of TFT structures manufactured by a conventional method, for explaining the manufacturing process.

FIG. 2A shows a first TFT structure. In the first structure, an island-shaped polysilicon layer 204 is formed on a grass substrate 201, and a gate insulation film 206 is formed on the grass substrate 201 so as to cover the polysilicon layer 204. A gate electrode 208 is formed on the gate insulation film 206 so as to be just above a central portion of the island-shaped polysilicon layer 204.

Lightly doped drain (LDD) regions 214 are formed by implanting n-type dopant ions such as P⁺ ions into the polysilicon layer 204 while using the gate electrode 208 as a mask. The LDD regions 214 have low n-type impurity concentration. After the formation of the LDD regions 214, barriers 211 are formed on side walls of the gate electrode 208. To form the barriers 211 only on the side walls of the gate electrode 208, an insulation film deposited on a whole surface of the substrate, for example, is etched by anisotropy etching so that regions of the insulation film on planar portions are removed.

After the formation of the barriers 211, the implantation of the n-type dopant ions such as P⁺ ions into the semiconductor layer is carried out again while using the gate electrode 208 and the barriers 211 as a mask, so that heavily doped source/drain regions 224 are formed in the semiconductor layer as shown in FIG. 2A. The heavily doped source/drain regions 224 are formed at both ends of the semiconductor layer so that inner ends thereof correspond to the outer ends of the barriers 211 respectively.

In the process of implanting ions in order to form the LDD regions 214 and the source/drain regions 224 shown in FIG. 2A, the ions are implanted with high acceleration energy by which the ions go through the gate insulation film 206.

FIG. 2B shows a second TFT structure. In the second structure, a polysilicon layer 204 is formed on a glass substrate 201 and a gate insulation film 206 is formed on the polysilicon layer 204, similar to the first structure shown in FIG. 2A. The second structure features that the gate insulation film 206 is patterned so as to remain only on a central portion of the polysilicon layer 204, that is, the gate insulation film 206 on other regions is removed. And a gate electrode 208 is formed on thus patterned gate insulation film 206 so that edges of the gate electrode 208 retard (be inward) from edges of the gate insulation film 206. In other words, the edges of the gate insulation film 206 projects from the edges of gate electrode 208.

P⁺ ions having low impurity concentration are implanted into thus structured TFT with acceleration energy by which the ions go through the gate insulation film 206. Further, the ions are implanted into the TFT again with low acceleration energy at which the ions are blocked by the gate insulation film 206. After the ion implantation with the low acceleration energy is carried out, the heavily doped source/drain regions 224 are formed in the polysilicon layer 204 so that inner ends thereof correspond to the edges of the gate insulation film 206 respectively.

Ions having low impurity concentration are implanted through the gate insulation film 206 into regions of the polysilicon layer 204 utilizing the gate electrode 208 as a mask so that the inner ends of the lightly doped regions 214 correspond to the edges of the gate electrode 208. In the outer exposed regions 224, the two ion implantations are done overlappedly. After the ion implantation, the LDD regions 214 having low impurity concentration are formed in the regions from the edges of the gate electrode 208 to the edges of the gate insulation film 206.

Feature in the process of forming the second TFT structure shown in FIG. 2B is that the LDD regions having low impurity concentration and the source/drain regions having high impurity concentration can be selectably formed just by controlling the acceleration energy for the series of ion implantation.

FIGS. 2C and 2D schematically show two types of ion sources for an apparatus for the non-mass analyzed ion implantation. FIG. 2C shows an RF ion source which has a pair of electrodes 220 and 221 to which, for example, electric power of 13.56 MHz is supplied in order to generate plasma 222 between the electrodes.

FIG. 2D shows a DC ion source using filaments which emit thermal electrons. Filaments 226 and 227 emit thermal electrons by resistance heating. The thermal electrons emitted by the filaments 226 and 227 generate plasma 228.

The conventional TFT structures formed on a large substrate such as a glass substrate could not show excellent performance.

### SUMMARY OF THE INVENTION

It is an object of the present invention to provide a manufacturing method for manufacturing a thin film transistor showing excellent performance.

It is another object of the present invention to provide a thin film transistor showing excellent performance.

According to a first aspect of the present invention, there is provided a method of manufacturing a thin film transistor comprising the steps of: (a) forming a plurality of island-shaped semiconductor layers on a substrate having an insulative surface; (b) implanting dopant into first regions at outsides of a channel region in each of the semiconductor layers directly or through a thin insulation film whose thickness is equal to or less than 50 nm by ion implantation to form lightly doped regions; and (c) implanting dopant into regions at outsides of the first regions in each of the semiconductor layers directly or through a thin insulation film by non-mass analyzed ion implantation to form heavily doped source/drain regions whose impurity concentration is higher than that of the lightly doped regions.

According to another aspect of the present invention, there is provided a thin film transistors comprising: a substrate having an insulative surface; a plurality of island-shaped crystalline silicon layers formed on the substrate; a gate insulation film formed at a center of each of the crystalline silicon layers; a pair of lightly doped regions formed in each of the crystalline silicon layers outwards from edges of the gate insulation film; a pair of heavily doped source/drain regions whose impurity concentration is higher than that of the lightly doped regions, formed in each of the crystalline silicon layers outwards from edges of the pair of lightly doped regions; and a gate electrode formed on each of the gate insulation films, whose edges are retarded from edges of the gate insulation film.

Accordingly, the performance of the thin film transistor can be enhanced. Moreover, it is able to provide a thin film transistor capable of preventing time-dependent change of the characteristics.

### BRIEF DESCRIPTION OF THE DRAWINGS

FIGS. 1A to 1C are a cross sectional view and graphs for explaining a fundamental embodiment of the present invention;

FIGS. 2A to 2D are cross sectional views showing the TFT structures for explaining conventional techniques and diagrams for illustrating two kinds of ion sources;

FIG. 3 is a graph for studying the performance of the TFT manufactured by the conventional techniques;

FIGS. 4A, 4B and 4C are an equivalent circuit diagram and a plan view each showing the structure of a liquid crystal display device manufactured according to an embodiment of the present invention, and a schematic cross-section of the liquid crystal display device;

FIGS. 5A to 5G are cross sectional views of a substrate for illustrating processes of manufacturing TFTs according to the embodiment of the present invention;

FIGS. 6A to 6D are plan views showing the structure of the TFT which forms a pixel in the liquid crystal display device according to the embodiment of the present invention;

FIGS. 7A to 7D are cross sectional views of a substrate for illustrating processes of manufacturing TFTs according to another embodiment of the present invention;

FIGS. 8A to 8D are cross sectional views of a substrate for illustrating processes of manufacturing a TFT according to a still another embodiment of the present invention;

FIGS. 9A to 9C are cross sectional views of a substrate for illustrating processes of manufacturing a TFT according to a further embodiment of the present invention;

FIGS. 10A to 10F. are cross sectional views of a substrate for illustrating processes of manufacturing TFTs according to a still further embodiment of the present invention;

FIGS. 11A to 11C are a cross sectional view and plan views showing structures of the double-gate TFT;

FIGS. 12A to 12D are a cross sectional view showing the structure of an asymmetric TFT and equivalent circuit diagrams showing circuits each having the asymmetric TFT;

FIGS. 13A and 13B are equivalent circuit diagrams showing structures of the sampling circuit using the TFT according to the above mentioned embodiment;

FIGS. 14A to 14F are cross sectional views of a substrate for illustrating processes of manufacturing a bottom-gate type TFT according to a yet still another embodiment of the present invention; and

FIGS. 15A to 15C are cross sectional views of a substrate for illustrating steps of manufacturing a bottom-gate type TFT according to a yet still further embodiment of the present invention.

### DETAILED DESCRIPTION OF THE PREFERRED EMBODIMENT

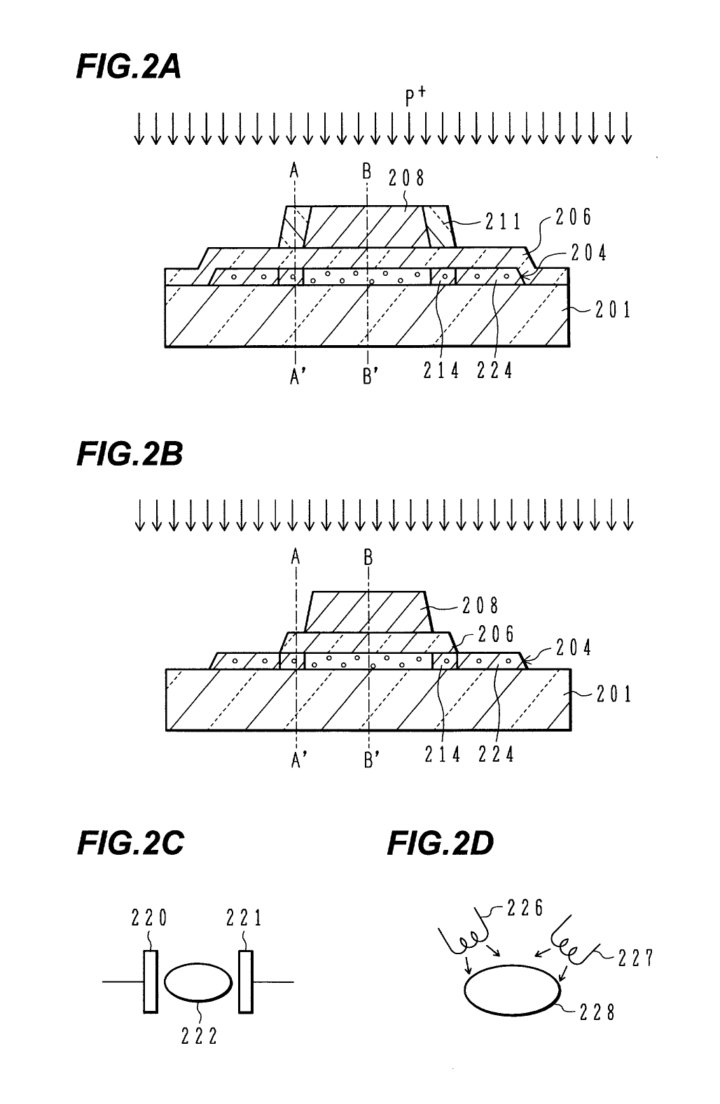

The inventor of the present invention studied why the performance of polysilicon TFTs as shown in FIGS. 2A and 2B cannot be fully improved. Dopant ions must be accelerated with a high voltage in order to implant them through a gate insulation film into a polysilicon layer.

The highly energized ions going through the gate insulation film generate various defects which are disadvantage for the gate insulation film. The polysilicon layer also causes various defects simultaneously. Since it is unable to heat the TFTs formed on a glass substrate, it is difficult to recover the defects by thermal treatment.

Further, in a case of non-mass analyzed ion implantation, implantation of various ion species are also implanted. When dopant is hydride, hydrogen ions are generated and implanted into a target semiconductor layer. The hydrogen ions may be implanted deeper than other ions because ionic radius of the hydrogen ion is smaller than that of other ions.

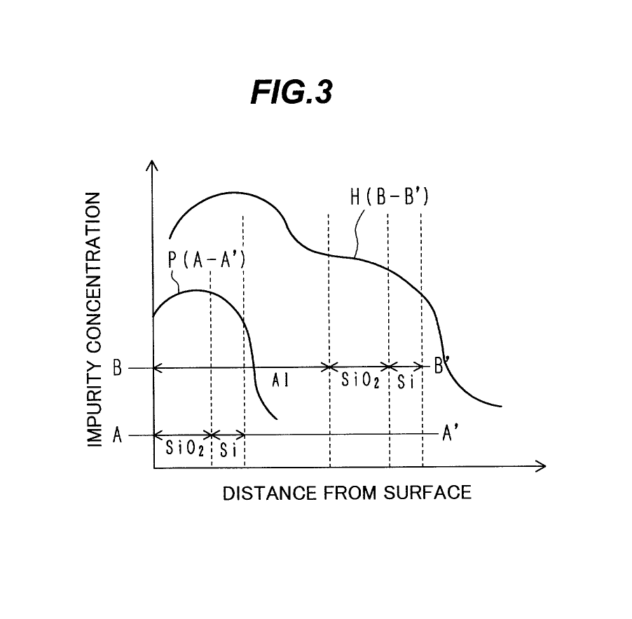

FIG. 3 is a graph showing how phosphorous being distributed along a line A-A′ in FIGS. 2A and 2B and how hydrogen being distributed along a line B-B′ in FIGS. 2A and 2B. A horizontal axis of the graph represents distance from a surface and a vertical axis thereof represents dopant concentration.

According to the phosphorous distribution shown in the graph, dopant concentration of the implanted phosphorous peaks in the gate insulation film 206 which covers the polysilicon layer. And the shown dopant concentration decreases in the polysilicon layer while realizing the desired concentration. The phosphous distribution also extends into the glass substrate with some concentration. Implanted hydrogen goes through the aluminum gate electrode. The hydrogen is widely distributed in layers under the gate electrode, that is, the gate insulation film, the polysilicon layer, and the glass substrate as shown in the graph representing hydrogen distribution along the line B-B′ which corresponds to the gate electrode.

The following table shows a relationship between the peak depth of implanted hydrogen ions and an acceleration voltage.

Relationship between Peak Depth of
Implanted Hydrogen Ions and Acceleration Voltage

| Acceleration | | |
|---|---|---|
| Voltage | H⁺ ions | H₂⁺ ions |
| 10 KV | 120 nm | 60 nm |
| 30 KV | 280 nm | 140 nm |
| 60 KV | 500 nm | 250 nm |
| 80 KV | 640 nm | 320 nm |

Since the depth of the implanted H⁺ ions is about twice as deeper as that of the implanted H₂⁺ ions, channel regions (a silicon layer under the gate electrode) are mainly influenced by H⁺ ions and LDD regions (a silicon layer under an SiO₂ film) are mainly influenced by H₂⁺ ions.

Implanted H⁺ ions go through the gate electrode and the gate insulation film and easily reach an SiO₂/Si interface and the channel region (along the line B-B′) when the acceleration voltage becomes greater than 50-60 kV where, for example, in the case where the gate insulation film is 120 nm thick, a gate electrode film is 300 nm thick and an Si active layer is 50 nm thick. Accordingly, the SiO₂/Si interface and Si bulk are damaged by H⁺ ions implanted by the conventional technique which implants the H⁺ ions into the LDD regions with a high acceleration voltage (50 to 60 kV or higher).

Regions of the gate insulation film which are not covered with the gate electrode are seriously damaged by ion collision caused by large amount of P⁺ ions. Moreover, many carriers are trapped at an interface between the gate insulation film and the polysilicon layer. Generally, heat treatment with a temperature of 500 to 600 degrees Celsius or higher is required to recover the damages on the gate insulation film caused by the ion collision.

When the TFT employs a metal gate electrode made of aluminum or the like, an allowable maximum temperature for the heat treatment is up to approximately 450 degrees Celsius. Damages in the gate insulation film is hardly recovered by the heat treatment with such a low temperature. And the damages remaining in the gate insulation film will descend the TFT's electrical performance and its reliability.

Laser annealing for recovering damages caused by ion implantation and activating implanted impurities has been established. The laser annealing realizes damage recovery by annealing target objects such as a polysilicon layer on a glass substrate without heating the glass substrate extremely.

An XeCl laser beam having a wavelength of 308 nm, a KrF laser beam having a wavelength of 248 nm, or the like is used for the laser annealing.

It is difficult to anneal a semiconductor layer under a gate insulation film by the laser annealing, because the gate insulation film absorbs the laser beam greatly, thus, the laser beam reached the semiconductor layer is weakened. This fact brings difficulties in annealing exposed source/drain regions and the LDD regions covered with the gate insulation film under the same condition.

Moreover, once hydrogen is implanted into the polysilicon layer under the gate electrodes, it is difficult to extract the implanted hydrogen later. In such a case, extra hydrogen exists in the polysilicon layer. Therefore, H₂O may be formed in the semiconductor layer if O or HO penetrates into the polysilicon layer during process of forming an interlayer insulation film. Thus formed H₂O will be polarized easily by applied electric field. The polarized H₂O may change the characteristics of the semiconductor device.

In a case where the gate insulation film has its ends on the polysilicon layer surface as shown in FIG. 2B, the laser annealing causes the gate insulation film to have grained unevenness on its sides. This may also descend the performance of the semiconductor device.

The inventor of the present invention proposes a solution for the above problems. The solution includes ion implantation with an acceleration voltage which prevents H ions from penetrating into the semiconductor layer after passing through the gate electrode, and forming the gate insulation film except on the LDD regions and the source/drain regions so that the LDD regions and the source/drain regions can be laser annealed under the same condition.

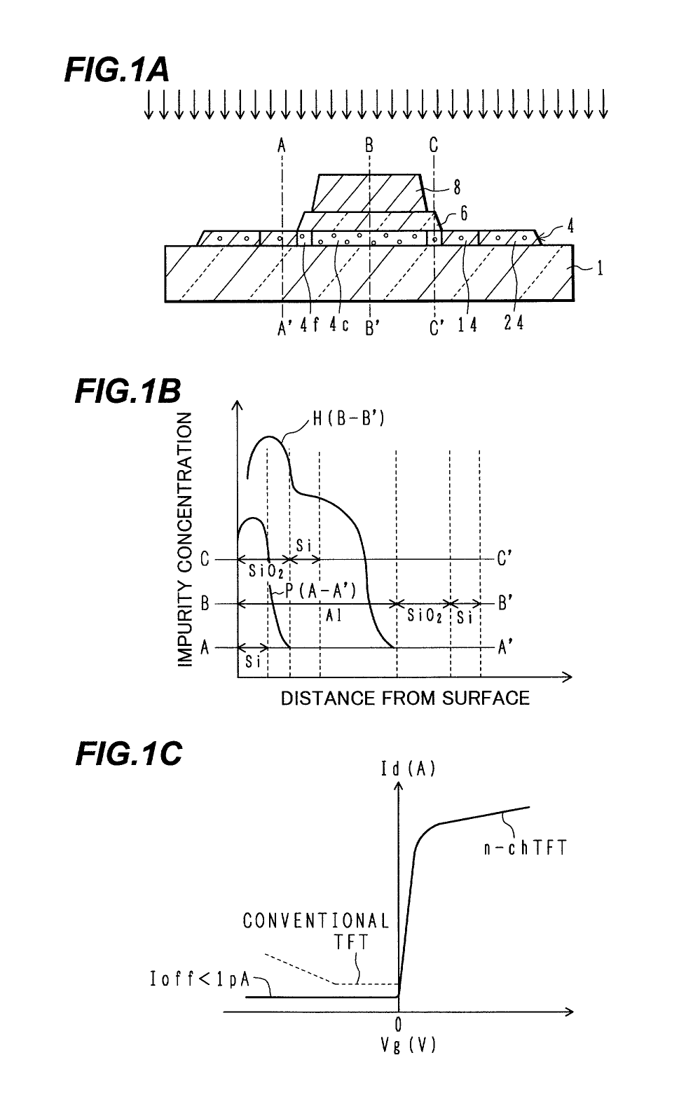

The structure of a thin film transistor according to a fundamental embodiment of the present invention and its characteristics will be explained with reference to FIGS. 1A to 1C. FIG. 1A is a cross sectional view showing a substrate in manufacturing process of the thin film transistor. FIG. 1B is a graph showing how phosphorous is distributed along a line A-A′ and how hydrogen is distributed along a line B-B′. FIG. 1C is a graph showing the characteristics of the thin film transistor manufactured by the process in this embodiment.

In FIG. 1A, an island-shaped polysilicon layer 4 is formed on a substrate 1 (glass substrate, or the like) having an insulative surface. A gate insulation film 6 made of an SiO₂ film or the like having a thickness equal to or greater than 50 nm, more particularly equal to or greater than 80 nm is formed on the surface of the polysilicon layer 4 at its center. And a gate electrode 8, for example, a metal layer gate electrode, having a thickness of 200 nm or larger, or an Si layer having a thickness of 500 nm or larger is formed on the gate insulation film 6 at its center.

A channel region 4c is an area in the polysilicon layer 4, which is a projection of the gate electrode 8 along a direction perpendicular to the substrate surface. Offset areas 4f are areas in the polysilicon layer 4 whose outer edges are registered with edges of the gate insulation film 6 and inner edges are registered with edges of the gate electrode 8. Areas in the polysilicon layer 4 which are not covered with the gate insulation film are doped intentionally. Low dose ion implantation with low acceleration energy, such as 30 keV or lower, more particularly around 10 keV or lower, is carried out while using the gate electrode 8 and the gate insulation film 6 as a mask, thus, areas in the polysilicon layer 4 which are not covered with the gate insulation film 6 become LDD regions 14.

And then, high dose ion implantation with low acceleration energy is carried out while using a newly formed resist mask or the like as a mask which covers target regions on the LDD regions, thus, the unmasked areas become heavily doped source/drain regions 24. Low acceleration energy such as 30 keV or less, more particularly around 10 keV or less is also suitable for this high dose ion implantation.

If the acceleration voltage for the heavy/light doping is set at 30 kV or less, peak depth of the implanted H⁺ ions becomes 280 nm or less, thus, the penetration of H⁺ ions into the channel region is prevented (B-B′ section). When the acceleration voltage is further lowered to be 10 kV or less, peak depth of the implanted H⁺ ions becomes 120 nm or less and that of the implanted H₂⁺ ions becomes 60 nm or less, thus, the penetration of the H⁺ ions into the channel region and that of the H₂⁺ ions (or H⁺ ions) into the LDD regions are prevented simultaneously (C-C′ section). Accordingly, preferable acceleration voltage for the heavy/light doping is equal to or less than 10 kV.

Enough amount of dopant ions can be implanted into target regions even if the acceleration energy is low, because such the target regions are exposed during the ion implantation. From the point of performance of the ion implanting apparatus, the acceleration energy for the ion implantation is preferably equal to or greater than 1 keV. The ion implantation with such the low acceleration energy prevents H ions or the like from being implanted into the channel region 4c through the gate electrode and the gate insulation film. Selected concentration of H in the channel region is preferably set at equal to or less than 10¹⁷ cm⁻³. The mask will be removed after the ion implantation into the source/drain regions is finished.

FIG. 1B shows how phosphorous is distributed along the line A-A′ (shown in FIG. 1A) in section and how hydrogen is distributed along the line B-B′ (shown in FIG. 1A) in section. The abscissa represents the distance from the surface and the ordinate represents the impurity concentration.

As indicated by a curve P (A-A′), the concentration of phosphorous peaks in the LDD regions in the polysilicon layer. The concentration of phosphorous is radically lowered in the substrate 1. The phosphorous concentration along the line C-C′ in accordance with the distance from the surface is similar to that shown by the line P (A-A′). Since the concentration of phosphorous decreases in the gate insulation film, a little phosphorous exists in the area of the polysilicon layer which is covered with the gate insulation film.

In a section including the gate electrode, the concentration of hydrogen is very high in the aluminum electrode but that is very low in the gate insulation film under the electrode. A little hydrogen exists in the channel region under the gate insulation film.

After the ion implantation is completed, laser annealing is applied to areas which is not covered with the gate insulation film, that is, exposed areas of the LDD regions 14 and the source/drain regions 24. Since those regions are exposed, they will be annealed well under the same annealing condition, thus excellent poly crystalline structure is obtained. Moreover, a laser beam is used efficiently because the laser beam is irradiated onto the polysilicon layer directly.

FIG. 1C is a graph showing the characteristics of a drain current versus a gate voltage in thus formed thin film transistor. The drain current shown in the graph radically increases as the forward gate voltage increases, that is, it shows excellent saturation characteristics. A leak current loff is constant and low such as 1 pA or lower, in spite of changes in a reverse polarity gate voltage. In the conventional TFTs, the leak current in accordance with the reverse polarity gate voltage was very large.

According to the TFT shown in FIG. 1A, it is able to reduce the leak current. Moreover, the reliability of the TFT is improved and its performance is stable with suppressed time change because H is not implanted into the channel region.

More detailed embodiment of the liquid crystal display will now be described.

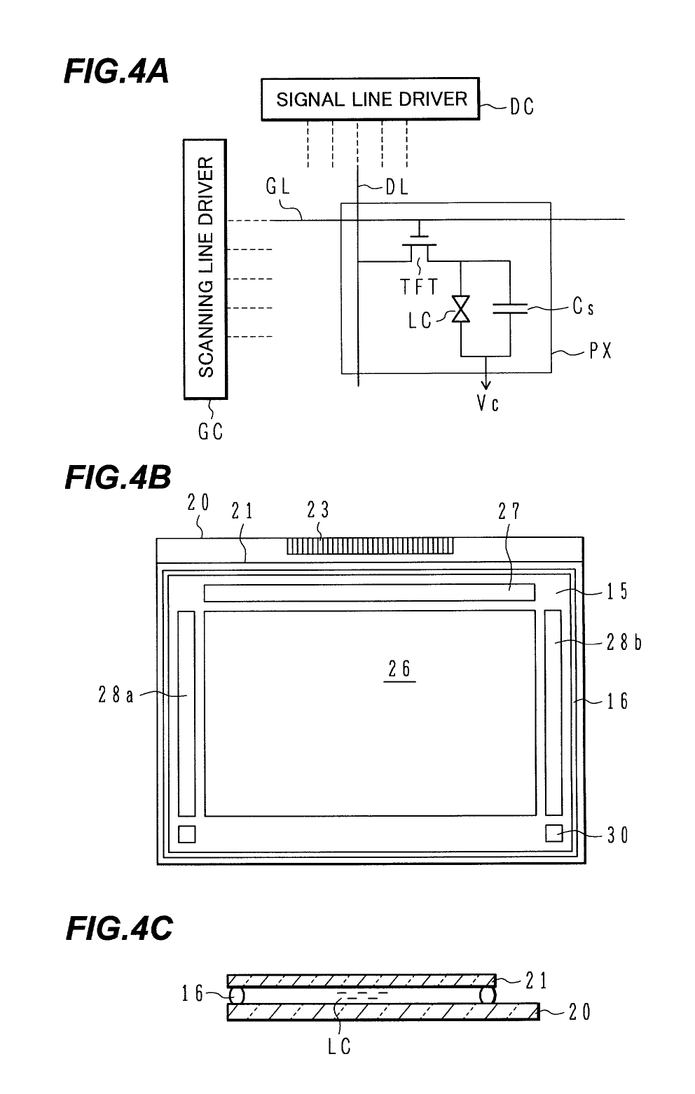

FIGS. 4A and 4B are an equivalent circuit diagram of the liquid crystal display and a plan view showing the structure of a display panel. FIG. 4A schematically shows an equivalent circuit of an active matrix type liquid crystal display.

As shown in FIG. 4A, a plurality of scanning lines GL are arranged in the horizontal direction, and a plurality of signal (data) lines DL are arranged in the vertical direction. A pixel PX is connected to each of intersections of the scanning line GL and the signal line DL. The pixel PX includes a TFT switching element, a liquid crystal cell LC, and a capacitor Cs. The liquid crystal cell includes a common electrode on a common electrode substrate, a pixel electrode on a TFT substrate, and a liquid crystal layer between the common electrode and the pixel electrode.

The pixel electrode acts not only as one of the electrodes in the liquid crystal cell but also as one of electrodes of the capacitor Cs. The other electrode of the capacitor Cs is formed on an insulation layer on the substrate on which the pixel electrodes are formed. The other electrode, that is, common electrode in the liquid crystal cell LC is formed on a substrate opposing to the TFT substrate. The common electrode is, for example, an extended transparent electrode on the whole surface of the substrate. The common electrode in the liquid crystal cell LC and the other electrodes of the capacitors Cs are connected to common potential Vc.

The scanning lines GL are driven by a scanning line driver (gate circuit) GC. The signal lines DL are driven by a signal line driver (drain circuit) DC. Each of the scanning lines GL activates the pixels PX on one line, and the signal line driver DC supplies image data to the activated pixels.

FIG. 4B schematically shows the plan structure of the liquid crystal display panel. The TFT substrate 20 and the common electrode substrate 21 are arranged so as to be opposing to each other while sandwiching the liquid crystal layer therebetween. The pixels are formed on a display area which is a central portion of the TFT substrate 20, and peripheral circuits are arranged around the electrodes. As shown in FIG. 4B, a drive circuit 27 such as the signal line driver is arranged along one of long sides of a display section 26, and peripheral circuits 28a and 28b are arranged along both short sides of the display section 26. A seal 16, which seals the both substrates to form a room to be filled with the liquid crystal, is arranged so as to surround the peripheral circuits.

Transfers 30 are provided for establishing electric connections between the upper and lower substrates. The display section 26 at center of the panel comprises, for example, a transmission or reflection type liquid crystal display. In a case of an HDTV, for example, the liquid crystal display has 1920 by 1080 pixels. Since the common electrode substrate 21 is smaller than the TFT substrate 20, offset side of the TFT substrate 20 is exposed. A connector terminal 23 is formed on the exposed portion.

The peripheral circuits 27, 28a and 28b are polysilicon TFT circuits. A light shield 15 is preferably arranged over those peripheral circuits in order to shade them from lights. It is preferable that the light shield 15 is placed on an inner surface or an outer surface of the common electrode substrate 21. In a case where the light shield 15 is formed on the inner surface of the common electrode substrate 21, the light shield 15 is preferably made of an insulation member in order to reduce floating capacity. For example, at least the signal driver is shaded by an insulating light shield 15.

The TFTs are formed in the display section, each for each pixel, which may be an n-channel TFT. The peripheral circuits are preferably CMOS circuits. N-channel TFTs and p-channel TFTs should be formed in order to realize the CMOS circuits.

FIG. 4C shows a schematic cross section of a liquid crystal display. A liquid crystal layer LC comprising liquid crystal molecules is sandwiched between the TFT substrate 20 and the common electrode substrate 21.

Manufacturing process of the n-channel TFT and the p-channel TFT will now be described.

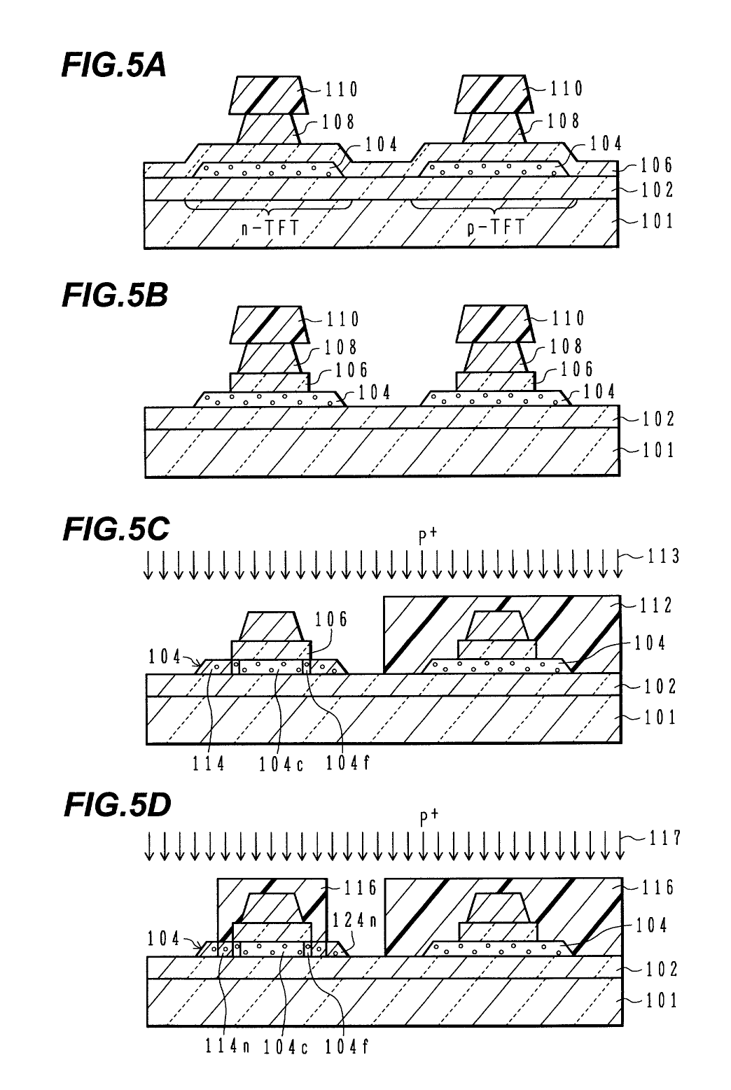

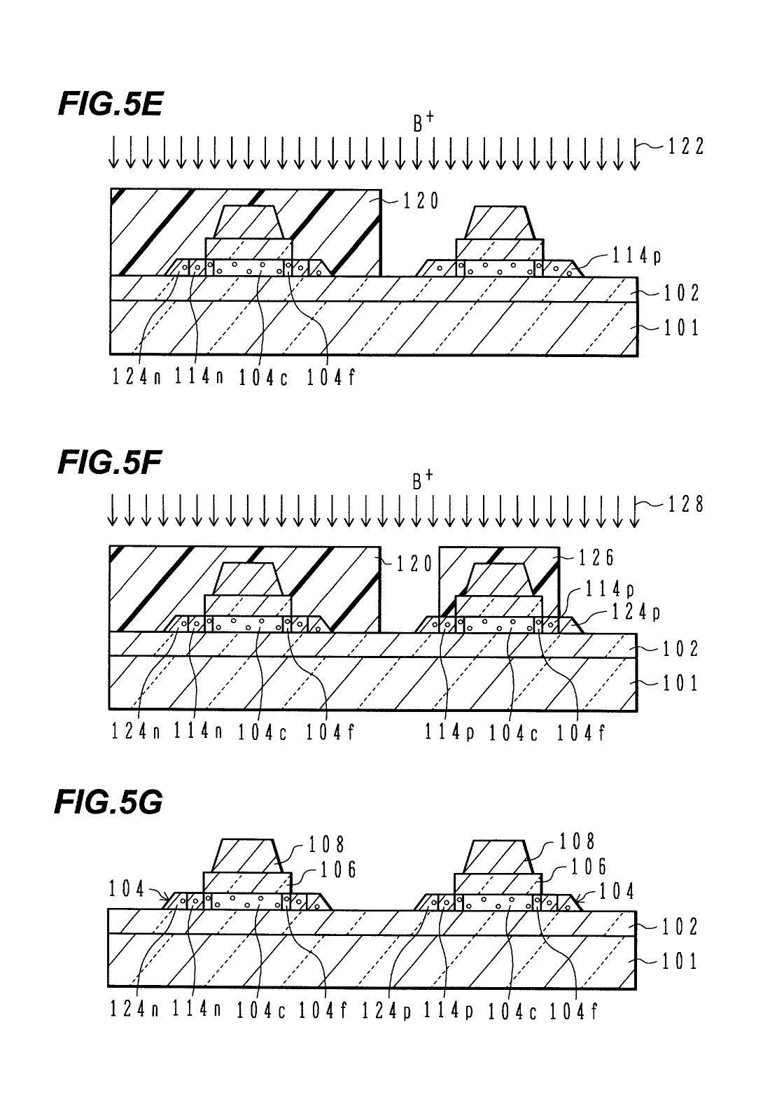

FIGS. 5A to 5G show manufacturing process of the CMOS TFT according to the embodiment of the present invention.

Plasma enhanced (PE) CVD is carried out to form an underlie SiO₂ film 102 on a glass substrate 101 as shown in FIG. 5A. The thickness of the SiO₂ film 102 is preferably selected in a range of 100 to 500 nm, and more preferably approximately 200 nm. And the PECVD is carried out again to form an amorphous silicon layer 104 on the underlie SiO₂ film 102. The thickness of the amorphous silicon layer 104 is preferably in a range of 30 to 100 nm, and more preferably approximately 40 nm. It is preferable that the amorphous silicon layer 104 is a low hydrogen containing film wherein the hydrogen concentration is less than 5%.

The formed amorphous silicon layer 104 may be heated to a temperature of 450 degrees Celsius for approximately 1 hour to remove hydrogen from the amorphous silicon layer 104 according to necessity. Then, crystallization is carried out by scanning the amorphous silicon layers 104 with an eximer laser beam such as XeCl and KrF. In a case of using the XeCl laser beam having a wavelength of 308 nm, it is preferable that the energy density is set in a range of 300 to 450 mJ/cm² and scanning is done with a linear beam.

The amorphous silicon layer is converted into a polysilicon layer which preferably has an average grain size of equal to or greater than 10 nm. The amorphous silicon layer may also be converted to micro crystals, the average grain size of which is smaller than 10 nm. The peripheral circuits may be polycrystalline while the display section may be micro crystals. In this specification, a term “crystalline” includes both the polycrystal and micro crystal.

After the conversion of the amorphous silicon layers into the polysilicon layers 104, the PECVD is a gate insulation film 106 formed of an SiO₂ layer having a thickness equal to or greater than 50 nm, for example, 120 nm is formed by DECVD. A gate electrode layer of aluminum alloy (AINd, AlSe, or the like) is formed on the gate insulation film 106 by sputtering. The thickness of the gate electrode layer is in a range of 300 to 500 nm, and more preferably in a range of 300 to 350 nm.

A resist pattern 110 is formed on the gate electrode layer, and then the gate electrode layer is etched by wet etching or isotropic dry etching to form gate electrodes 108. Etchant for the wet etching may be mixed acid etchant, for example, including nitric acid, acetic acid and phosphoric acid. Because of the isotropic etching, the side wall of each gate electrode 108 is retarded from the side wall of the resist mask 110. The length of retardation is selected in a range of 100 to 400 nm, and preferably at approximately 200 nm.

As shown in FIG. 5B, anisotropic etching is applied to the gate insulation film 106 using the resist mask 110 as a mask. For example, the gate insulation film 106 is etched by reactive ion etching (RIE) with an etching gas of CHF₃.

Since the resist mask 110 extends outside from the gate electrode 108, the gate insulation film 106 after the etching projects from the edge of the gate electrode 108, for example, by a width of approximately 200 nm. The resist mask 110 is removed after the etching is finished.

As shown in FIG. 5C, ion doping of low dose P⁺ ions 113 with low acceleration energy is carried out while the p-channel TFT region is covered with a resist mask 112. For example, implantation of P⁺ ions 113 is carried out at a dose of 5×10¹² cm⁻² and an acceleration energy of 10 to 30 keV. Thus, LDD regions 114 are formed in the areas in the silicon layer 104 for the n-channel TFT which are not covered with the gate insulation film. After the formation of the LDD regions 114 is completed, the resist mask 112 is removed.

As shown in FIG. 5D, another resist mask 116 is formed to cover the p-channel TFT and the LDD regions 114n for the n-channel TFT. Ion doping of P⁺ ions 117 at a high dose with low acceleration energy is applied to the exposed portions in the polysilicon layer 104, that is, portions which are not masked by the resist mask 116. For example, ion implantation of the P⁺ ions 117 is at a dose of 5×10¹⁴ cm⁻² and at an acceleration energy of 10 to 30 keV. After the ion implantation is completed, the resist mask 116 is removed.

The exposed portions of the polysilicon layer 104 are heavily doped with the P⁺ ions 117, thus, heavily doped source/drain regions 124n are formed. An apparatus for non-mass-analyzed ion implantation is suitable for performing such a high dose ion implantation. The low dose ion implantation shown in FIG. 5C is preferably carried out in an apparatus for the non-mass-analyzed ion implantation having a DC ion source which has filaments for emitting thermal electrons. In an apparatus for non-mass-analyzed ion implantation using an RF ion source, it is difficult to control the dose of the ions low. In a case where the ion implantation steps shown in FIGS. 5C and 5D are carried out in series in a single ion implantation apparatus, the apparatus for the non-mass-analyzed ion implantation with the DC ion source is preferably selected because it is suitable for such ion implantation. As shown in FIG. 5E, a resist mask 120 is formed which covers the n-channel TFT, and then, B⁺ ion doping with low acceleration energy at a low dose is carried out to form LDD regions 114p for the p-channel TFT. For example, ion implantation of the B⁺ ions 122 whose dose is approximately 5×10¹² cm⁻² is carried out by accelerating B⁺ ions 122 with the acceleration energy of 10 to 30 keV. As a result, the LDD regions 114p are formed. After the ion implantation, the resist mask 120 is removed.

As shown in FIG. 5F, a resist mask 126 is formed to cover the n-channel TFT and to partially cover the LDD regions 114p. Then, doping of high dose B⁺ ions 128 is carried out at a low acceleration energy. For example, the doping of the B⁺ ions 128 whose dose is 5×10¹⁴ cm⁻² is carried out with the acceleration energy of 10 to 30 keV.

Exposed portions of the polysilicon layer 104 for the p-channel TFT, that is, portions which are not masked by the resist mask 126 are heavily doped with B⁺ ions. Thus, heavily doped source/drain regions 124p are formed. Masked portions remain as the LDD regions 114p. Then, the resist mask 126 is removed. Similar to the above described ion implantation steps, the ion implantation steps shown in FIGS. 5E and 5F are also carried out in the apparatus for non-mass analyzed ion implantation. The ion source having the thermal electron emitting filaments is suitable for carrying out the small dose ion implantation with excellent controllability. Hereinafter, the reference numeral 114 may denote each or whole of the LDD regions, and the reference numeral 124 may denote each or whole of the source/drain regions.

FIG. 5G shows the structure of the TFT after the ion implantation process is completed. The LDD regions 114 and the source/drain regions 124 are damaged by the ion implantation. The implanted dopant is still inactive. Laser annealing with a laser beam 130 such as the XeCl is carried out from the above. Since the LDD regions 114 and the source/drain regions 124 are exposed, those regions can effectively absorb the laser beam.

Because the ion implantation is carried out with low acceleration energy, hydrogen is hardly implanted into the channel regions 104c covered with the gate electrode. In each TFT, offset regions 104f corresponding to the portions of the gate insulation film 106 which are not covered with and extending outside the gate electrode 108 are formed between the channel region 104c and the LDD region 114. These offset regions 104f are effective in reducing the electric field.

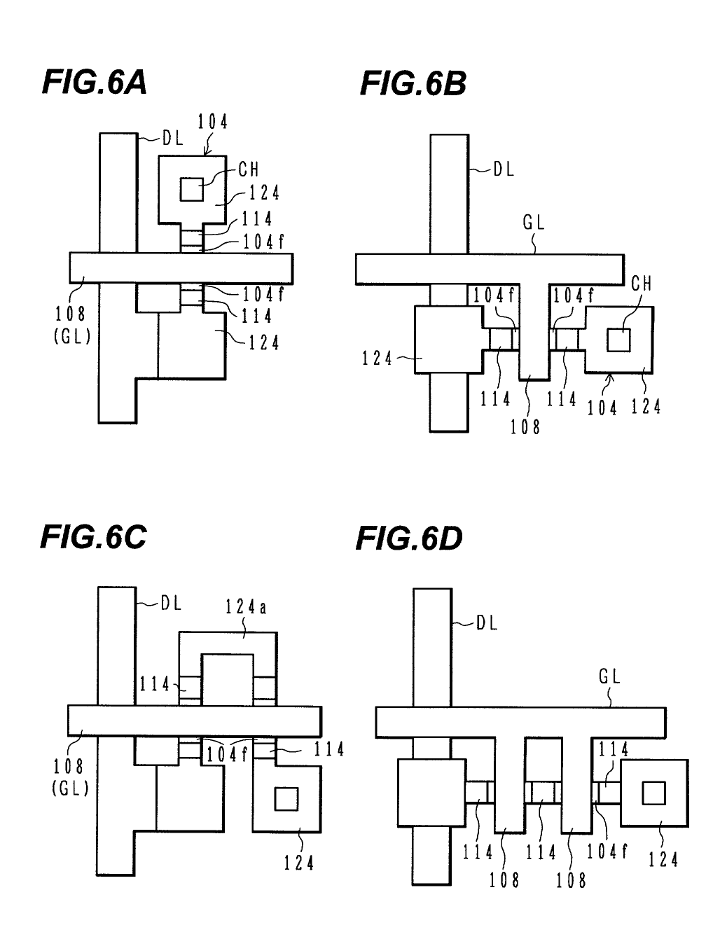

The LDD regions are easily depleted, therefore, these are also effective in reducing the electric field when a high voltage is applied between the gate electrode and the source/drain region. Since the damages caused by the ion implantation are thus recovered well, the completed TFT will show excellent performance. Moreover, hydrogen is prevented from being implanted into the channel region, and the TFT can keep its excellent performance ability without influenced by time dependent changing. FIGS. 6A to 6D show plan structures of pixel unit including the TFT which can be manufactured by the manufacturing process described with reference to FIGS. 5A to 5G or a modified manufacturing process thereof.

In FIG. 6A, each of the vertically arranged signal lines DL has connecting portions each of which projects laterally from the signal line DL. The connecting portion connects the signal line DL and the TFT. The semiconductor layer 104 is formed so as to partially overlaps the projected portion of the signal line DL. The semiconductor layer 104 comprises wide regions sandwiching a striped region. The semiconductor layer is arranged so that the scanning line GL overpasses just above a central portion of the striped region. The scanning line GL also act as the gate electrode 108. There is the gate insulation film between the gate electrode and the central portion of the striped region.

The central portion of the striped region below the gate electrode 108 acts as the channel region. The offset regions 104f are formed so as to sandwich the channel region. Illustration of the gate insulation film covering the offset regions 104f is omitted in the diagram. The LDD regions 114 are formed outside the offset regions 104f, and the source/drain regions 124, including the wide regions are further formed outside the LDD regions 114.

Then, an interlayer insulation film is formed on the surface of the substrate including the above described lamination structure. A contact hole CH is formed to reach one of the source/drain regions which is not connected to the signal line DL. This structure is simple because the scanning line itself acts as the gate electrode 108.

In FIG. 6B, the gate electrode 108 projects downward vertically from the scanning line GL, and the semiconductor layer is formed to extend in the lateral direction in the diagram. The semiconductor layer is arranged, at one end, to overlap and be connected with the signal line DL. The positional relationship between the gate electrode 108 and the semiconductor layer 104 is the same as that shown in FIG. 6A. FIG. 6B shows the source/drain regions whose widths corresponding to the direction of the striped region are different from each other, however, the source/drain regions may have the same widths.

FIGS. 6C and 6D show the structures of double-gate type TFTs. In the structure shown in FIG. 6C, the striped region as shown in FIG. 6A is elongated and bent in an inverted U-shape, and hence intersects the gate electrode 108 twice. Two sets of the offset regions 104f and the LDD regions 114, each set has the same structure as that of the single-gate type TFT shown in FIG. 6A, are formed at the intersections. A heavily doped region 124a is formed at the curved portion of the striped region connecting the LLD regions. This heavily doped region 124a reduces ON resistance of the TFT.

FIG. 6D shows a case where two gate electrodes 108 extend downward vertically from the scanning line GL, and the offset regions 104f are formed to sandwich each of the gate electrodes 108, and the LDD regions 114 are formed outside the offset regions 104f. In this structure, single LDD region 114 can be provided between the gate electrodes 108 by adjusting the distance between the gate electrodes 108. Other structural features are the same as those of the single-gate type TFT shown in FIG. 6B.

To form such the double-gate type TFT, shape of polysilicon layers each corresponding to a desired TFT shape, patterns of the gate electrodes formed on the polysilicon layers and resist mask patterns used for ion implantation with low acceleration energy and large dose is preferably arranged during the above described manufacturing process.

In the n-channel TFT, hot carriers may be generated when a high voltage is applied between the gate and drain, and deteriorate the performance of the n-channel TFT. Forming the LDD regions is one solution for preventing the performance of the n-channel TFT from being deteriorated by the hot carriers. On the contrary, the performance of the p-channel TFT is hardly deteriorated by the hot carriers.

Therefore, the LDD regions may be formed only in the n-channel TFT. In other words, LDD regions in the p-channel TFT may be omitted. The process of manufacture can be simplified and the time needed for manufacture can be shortened. Further, the number of masks can be reduced by employing inverting doping.

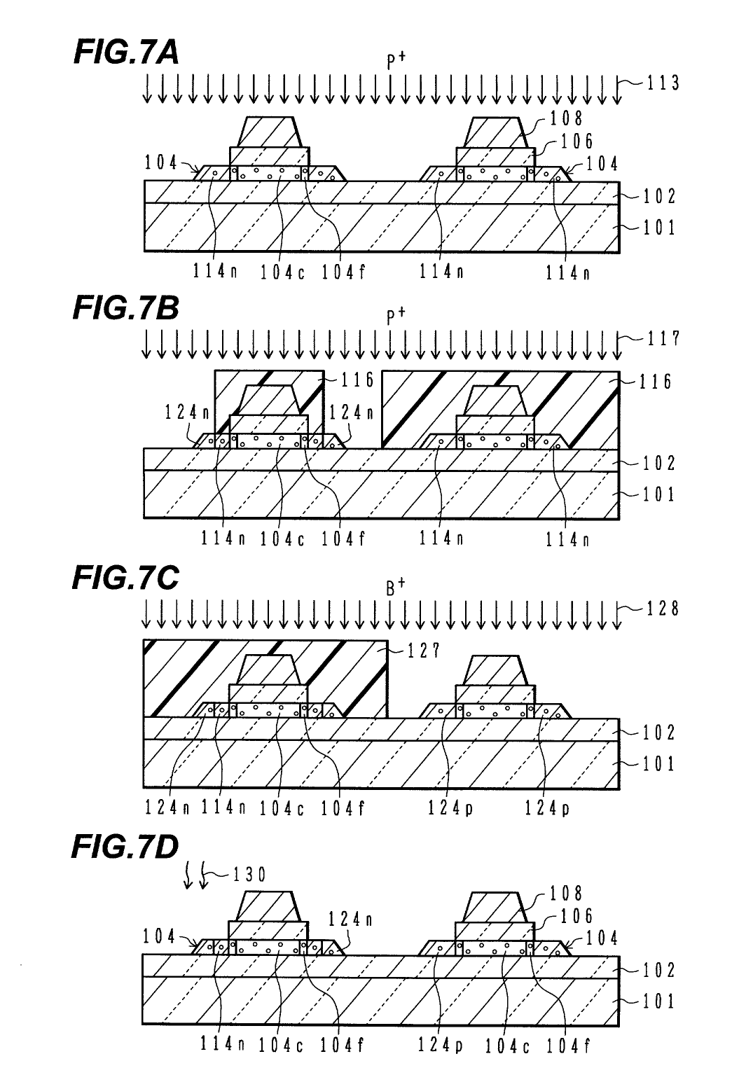

FIGS. 7A to 7D are cross sectional views for explaining the process of forming the LDD regions only in the n-channel TFT.

FIG. 7A shows the substrate after the resist mask is removed, after the process shown in FIGS. 5A and 5B. Small dose ions, for example, 5×10¹² cm⁻² P⁺ ions 113 are implanted into the substrate with low acceleration energy, for example, 10 to 30 keV, to form n-type LDD regions 114n for both n-type TFT and p-type TFT. Since there is no mask during the ion implantation, n-type dopant is also implanted into the p-channel TFT. N-type regions will be inverted into p-type regions later by doping p-type dopant into the n-type regions.

As shown in FIG. 7B, implantation of large dose P⁺ ions 117 is carried our with low acceleration energy after formation of the resist mask 116 which covers the whole p-channel TFT and the target LDD regions for n-channel TFT. For example, P⁺ ions 117 whose dose is 5×10¹⁴ cm⁻² are implanted with the acceleration energy of 10 to 30 keV. Exposed regions in the semiconductor layer for the n-channel TFT become n⁺-type source/drain regions 124 The n⁻-type LDD regions which are covered with the resist mask 116 but not covered with the gate insulation layer remain. Then the resist mask 116 is removed.

Another resist mask 127 is formed to cover the n-channel TFT as shown in FIG. 7C. Then the doping of large dose B⁺ ions 128 is carried out with low acceleration energy using the resist mask 127 as an implantation mask. For example, implantation of the B⁺ ions 128 whose dose is 5×10¹⁴ cm⁻² is carried out with acceleration energy of 10 to 30 keV. This large dose ion implantation converts the n-type regions in the p-channel TFT into p⁺-type source/drain regions 124p. Then the resist mask 127 is removed.

The semiconductor layer 104 for the n-type TFT comprises the channel region 104c, the offset regions 104f, the LDD regions 114n and heavily doped source/drain regions 124n as shown in FIG. 7D. The p-channel TFT comprises the offset regions 104f sandwiching the channel region 104c, and the heavily doped source/drain regions 124p directly outside the offset regions 104f.

Laser annealing is applied to the regions in which ions are implanted. A laser beam 130 as the XeCl laser is irradiated onto the regions, to activate the implanted impurities and recover the damages caused by the ion implantation. Because the ion-implanted regions are exposed, they can absorb the laser beam effectively and uniformly, thus, the laser annealing will show excellent result with a shorter period of time.

In the above described embodiment, the resist mask for masking the LDD regions is formed by photolithographic method. Another method not using photolithography may be employed to form a mask for the ion implantation.

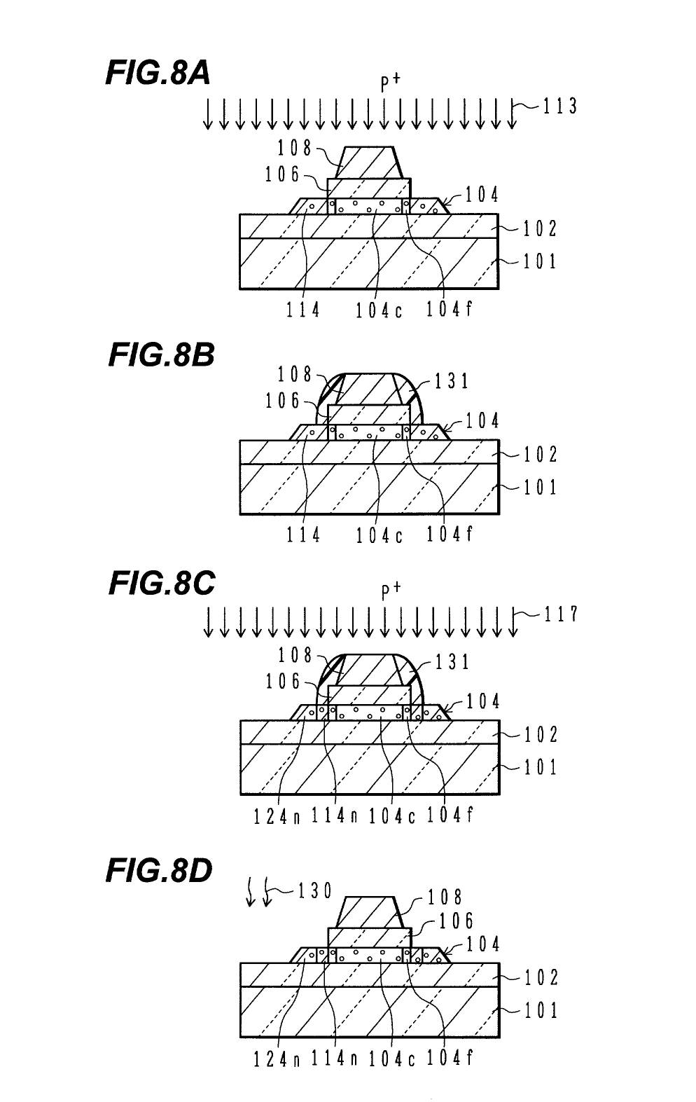

FIGS. 8A to 8D show process of manufacturing a TFT according to another embodiment of the present invention.

FIG. 8A shows doping process where implantation of small dose P⁺ ions is carried out with low acceleration energy to form the LDD regions. For example, implantation of P⁺ ions 113 at a dose of 5×1012 cm⁻² is carried out at an acceleration energy of 10 to 30 keV, to form LDD regions 114.

After the small dose ion implantation at a low acceleration energy is done, an insulation film 131, for example of polyimide, is formed on the surface of the substrate as shown in FIG. 8B. Then, anisotropic etching is carried out to leave side wall spacers 131 on side walls of the gate electrode and the gate insulation film. The desired widths of the LDD regions to be blocked can be selectable by controlling the thickness of the side wall spacers 131.

As shown in FIG. 8C, large dose P⁺ ions 117 are implanted at a low acceleration energy into the substrate provided with the side wall spacers 131. For example, implantation of the P⁺ ions 117 is carried out at a dose of 5×10¹⁴ cm⁻² and an acceleration energy of 10 to 30 keV. Exposed regions of the semiconductor layer become heavily doped source/drain regions 124n.

As shown in FIG. 8D, the side wall spacers 131 are removed by O₂ ashing and the regions where the ions are implanted are laser annealed with the laser beam 130 such as the XeCl laser, to activate the impurities and recover the damages caused by the ion implantation.

According to this manufacturing process, number of masks is reduced by one. Even when the p-channel TFT is masked, a mask for masking the p-channel TFT may be of lower accuracy, that is, highly accurate photolithography is not necessary.

In the above described embodiment, the gate insulation film was single layered SiO₂ film and the LDD regions and the source/drain regions having implanted ions were exposed. The gate insulation film may have multi-layered structure. The LDD regions and the source/drain regions into which the ions are implanted may be covered with thin insulation films such as natural oxide films.

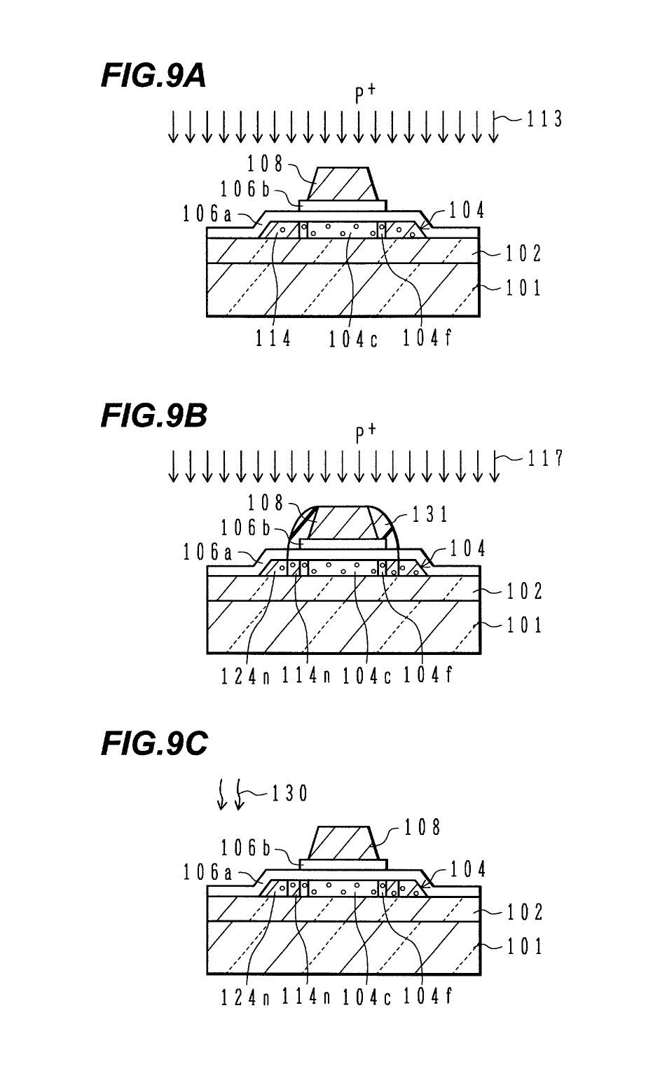

FIGS. 9A to 9D show process of manufacturing a TFT according to a further embodiment of the present invention.

A base SiO₂ film 102 is formed on a surface of a glass substrate 101, and island formed polysilicon layers 104 are formed on the base SiO₂ film 102 as shown in FIG. 9A. Then a gate insulation film including a lower SiO₂ film 106a and an upper SiNₓ film 106b is formed to cover the polysilicon layer 104. A gate electrode layer 108 is formed on the gate insulation film. Etching is carried out in the same manner as described in the above embodiments after the resist pattern is formed on the gate electrode layer 108.

The etching is carried out in such a manner that the gate electrode 108 and the upper SiNₓ layer 106b are etched, but the lower SiO₂ film 106a remains as an etching stopper. The thickness of the lower SiO₂ film 106a is selected approximately 30 nm or less, so that ion implantation through the lower SiO₂ film 106a can be done at an acceleration voltage of 30 kV or lower.

The P⁺ ions 113 are implanted through the lower SiO₂ film 106a into the semiconductor layer 104 at an acceleration voltage of 30 kV, and at a dose of, for example, 5×1012 cm⁻². As shown in FIG. 9B, the side wall spacers 131 made of polyimide or the like are formed on side walls of the gate electrode 108 and the upper SiNₓ layer 106bunder the gate electrode. Doping of large dose P⁺ ions 117 is carried out at a low acceleration energy while using the side wall spacers 131 and the gate electrode 108 as masks. For example, implantation of the P⁺ ions 117 whose dose is 5×10¹⁴ cm⁻² is carried out with the acceleration energy of equal to or less than 30 keV.

After the ion implantation, the heavily doped source/drain regions 124 are formed in the semiconductor layer 104 outside the side wall spacers 131. The LDD regions 114 remain under the side wall spacers 131. Then, the side wall spacers 131 are removed by O₂ ashing.

As shown in FIG. 9C, the TFT structure comprising the gate insulation film 106b under the gate electrode 108 having portions which slightly project from the gate electrode edges, and the gate insulation film 106a covering the whole surface of the semiconductor layer are formed. The regions where the ions are implanted in thus structured TFT are laser annealed with the laser beam 130 such as the XeCl laser. The laser beam 130 passes through the thin SiO₂ film 106a and reaches the semiconductor layer 104. The impurities therein are activated by the laser annealing, and, damages caused by the ion implantation are recovered.

The loss of the laser beam can be kept low because the regions in which the ions are implanted are merely covered with the thin and uniform SiO₂ film. The uniform thickness of the lower SiO₂ film 106a allows the LDD regions 114 and the source/drain regions 124 to be laser annealed under the uniformalized laser annealing condition.

In the above described embodiment, the upper surface of the gate electrode 108 is exposed during the ion implantation. Therefore, formation of an interlayer insulation film is necessary in a case where another wiring is formed on the gate electrode. An insulation film may be previously formed on the gate electrode in order to form another wiring thereon directly.

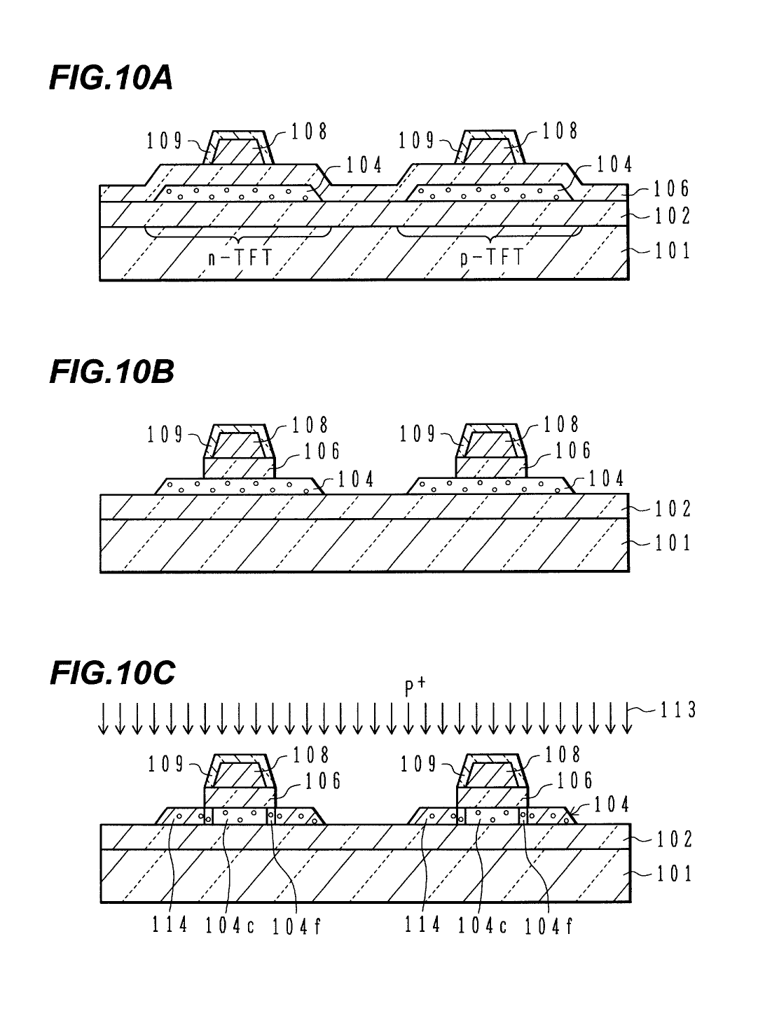

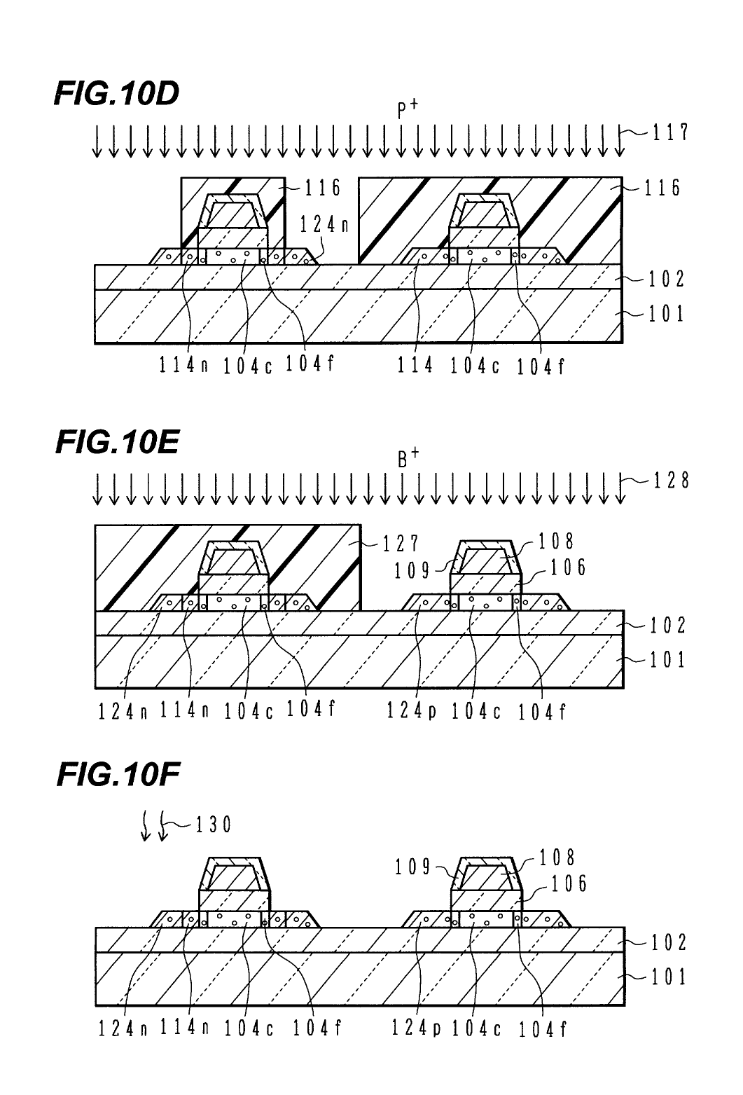

FIGS. 10A to 10F. show process of manufacturing a TFT according to still further embodiment of the present invention.

A base SiO₂ film 102 is formed on a surface of a glass substrate 101, and island-shaped polysilicon layers 104 are formed on the base SiO₂ film 102 as shown in FIG. 10A. A gate insulation film 106 is formed to cover the polysilicon layers 104, and the gate electrodes of aluminum or the like are formed on the gate insulation film 106. Then, the surfaces of the gate electrodes 108 are anodic oxidized in order to grow alumina layers 109. For the anodic oxidizing process, neutral electrolytic solution is preferably used to form barrier type alumina layers. For example, mixed solution of ethylene glycol, ammonia and a weak acid is used as the electrolytic solution. The thickness of each alumina layer is controllable by the anodic oxidization with applying a voltage of 80 to 200 V and the electrolytic solution having the above composition. The thickness of the alumina layers is selectable from the range of 0.1 to 0.3 micrometers.

The gate insulation film 106 under the gate electrodes 108 is patterned while using the gate electrodes 108 and alumina films 109 formed thereon as a mask, as shown in FIG. 10B. The gate insulation film 106 is etched by isotropic etching such as RIE with an etching gas of CHF₃. The alumina films 109 will define the offset regions.

FIG. 10C shows the implantation of small dose P⁺ ions 113 at a low acceleration energy while using the gate electrodes 108 covered with the alumina films 109 as a mask. For example, implantation of the P⁺ ions 113 at a dose of 5×10¹² cm⁻² is carried out at an acceleration energy of 10 to 30 keV, to form LDD regions.

A resist mask 116 which cover the whole p-channel TFT and the LDD regions of n-channel TFT is formed, as shown in FIG. 10D. Then, implantation of high dose P⁺ ions 117 is carried out at a low acceleration energy. This process is similar to the aforementioned process described with reference to FIG. 5D.

FIG. 10E shows doping of p-type B⁺ ions 128 at a low acceleration energy and a high dose. This doping is carried out after formation of a resist mask 127 covering the n-channel TFT. For example, doping of the B⁺ ions 128 is done at a dose of 5×10¹⁴ cm⁻² and an acceleration energy of 10 to 30 keV, thus, the ne-type regions in the p-type TFT are converted into p⁺-type regions. This process is similar to the aforementioned process described with reference to FIG. 7C. Then, the resist mask 127 is removed.

As shown in FIG. 10F, a laser beam 130 such as the XeCl laser is irradiated onto the regions, in which the ions are implanted, to activate the impurities, and to recover damages caused by the ion implantation. This laser annealing process is similar to that described in the above embodiments.

Thus formed TFTs have the alumina layers 109 covering the gate electrodes 108 (the scanning line GL) which prevents short circuit even if additional wiring is formed thereon directly. When an additional wiring is formed on an area where semiconductor layer 104 exists, it will electrically connected to the semiconductor layer 104. But the insulated gate electrodes are disposed as the scanning lines in the other wiring areas, where an additional wiring can be formed on the gate electrode directly.

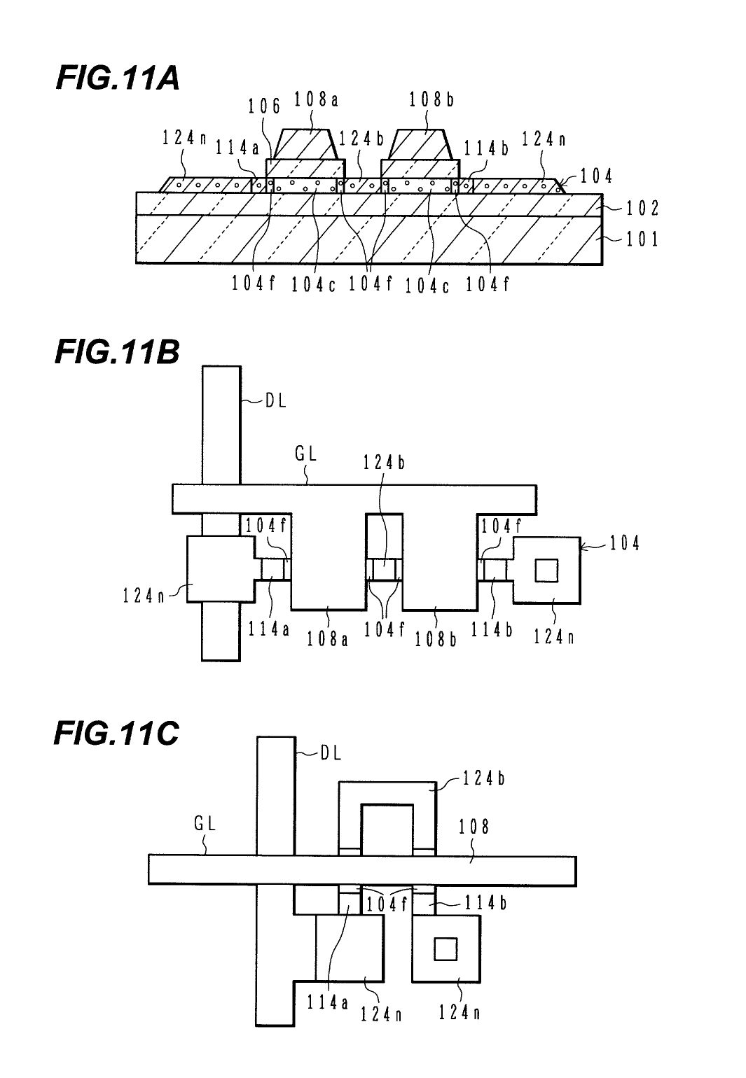

FIGS. 11A to 11C show modified structures of the double-gate TFT. FIG. 11A is a cross sectional view, and FIGS. 11B and 11C are plan views showing two structures.

As shown in FIG. 11A, a base SiO₂ layer 102 is deposited onto a glass substrate 101 and island-shaped polysilicon layers 104 are formed thereon. Two gate electrodes are formed at a central portion of each of the polysilicon layers 104. Each of the paired gate electrode structures includes gate insulation film 106 on the semiconductor layer 104 and the gate electrode 108 on the gate insulation film 106.

Between two gate electrodes 108a and 108b, not an LDD region but a heavily doped region 124b is formed. At the outsides of the gate electrodes 108a and 108b, the LDD regions 114a and 114b are formed adjacent to the gate electrodes. The heavily doped regions 124n and 124n are formed outsides the LDD regions 114a and 114b.

The same voltages are applied to the gate electrodes 108a and 108b, and this prevents large electric field from being applied to the semiconductor layer under the gate electrodes. Therefore, the LDD regions are omitted because reduction of the electric field is unnecessary in this area.

FIG. 11B is a plan view exemplifying the structure of the double-gate TFT shown in FIG. 11A. As illustrated, the signal line DL is arranged in the vertical direction, and the semiconductor layer 104 is formed so as to partially overlaps the signal line DL. The semiconductor layer 104 comprises a striped region sandwiched by wide regions. The gate electrodes 108a and 108b are arranged just above the striped region of the semiconductor layer 104. Formed between the gate electrodes and the striped region is the gate insulation film. Those gate electrodes are extended from the scanning line GL.

In the striped region between the gate electrodes 108a and 108b, the offset regions 104f are formed so as to adjoin the gate electrodes. The heavily doped region 124b is formed between pairs of the offset regions 104f.

In the semiconductor layer 104 at the left of the gate electrode 108a, the offset region 104f is formed so as to adjoin the gate electrode 108a, the LDD region 114a is formed at the left of the offset region 104f, and the heavily doped region 124n is formed at the left of the LDD region 114a.

In the semiconductor layer 104 at the right of the gate electrode 108b, the offset region 104f is formed so as to adjoin the gate electrode 108b, the LDD region 114b is formed at the right of the offset region 104f, and the heavily doped region 124n is formed at the right of the LDD region 114b.

This structure differs from the structure shown in FIG. 6D in that the heavily doped region is formed at the region between the pair of the gate electrodes in stead of the LDD region.

FIG. 11C is a plan view exemplifying a modification. This structure has a semiconductor layer which is bent at its center to form an inverted U-shaped. The scanning line GL, which also acts as the gate electrodes, intersects the striped region of the semiconductor layer twice. The heavily doped region 124b is formed at the curved region of the inverted U-shaped semiconductor layer so as to adjoin the offset regions. In this area, the semiconductor layer has no LDD region.

In a lower section of FIG. 11C (lower than the gate electrodes 108), the semiconductor layer 104 has the offset regions 104f each adjoining the gate electrodes, the LDD regions 114a and 114b adjoining the offset regions respectively, and the heavily doped regions 124n adjoining the LDD regions respectively. Other structural features are similar to those in the structure of the double-gate type TFT shown in FIG. 6C.

Voltages to be applied to the gate electrode, source electrode and drain electrode depend on what type of a circuit in which the TFTs are employed. Different voltages may be applied to the source electrode and the drain electrode. In such a case, forming symmetric LDD regions and heavily doped regions in both areas sandwiching the gate electrode is unnecessary. On the contrary, asymmetric structure is preferably selected to show better performance as the case may be.

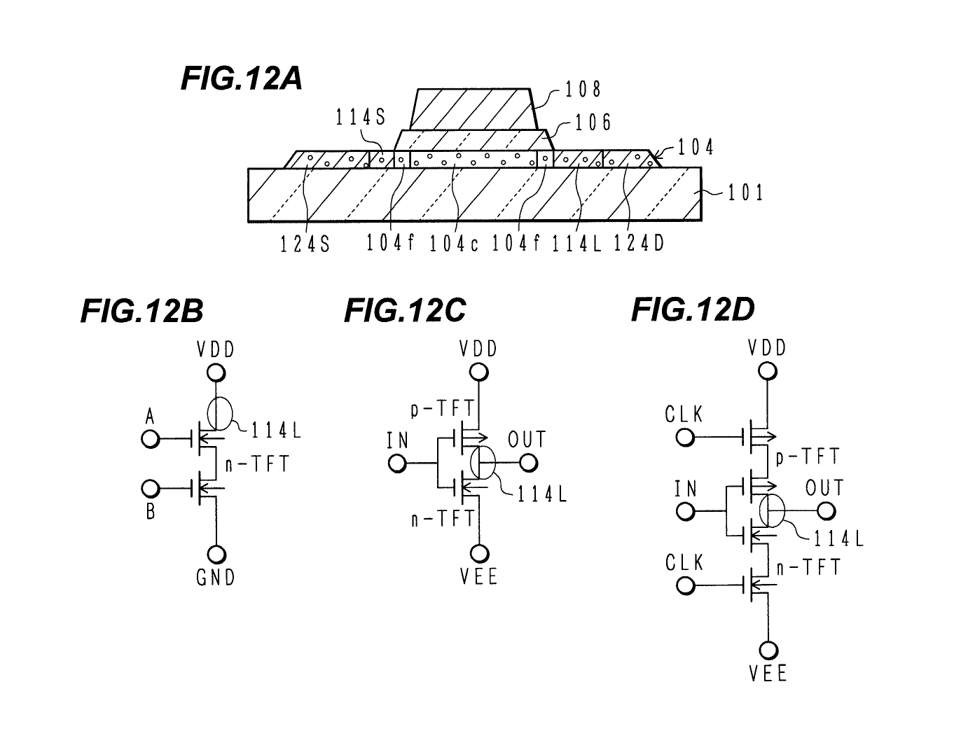

FIG. 12A shows the asymmetric structure employed in a TFT.

In FIG. 12A, a polysilicon layer 104 is formed on a substrate 101 having an insulative surface. On the center of the polysilicon layer 104, a gate insulation film 106 and a gate electrode 108 are formed. In an area at the left of the gate electrode 108, a short LDD region 114S is formed so that its inner edge corresponds to one edge of the gate insulation film 106, and a heavily doped source region 124S is formed next to the short LDD region 114S.

In an area at the right of the gate electrode 108, a long LDD region 114L is formed so that its inner edge corresponds to the other edge of the gate insulation film 106, and a heavily doped drain region 124D is formed next to the long LDD region 114L.

The long LDD region 124L reduces the electric field effectively even if a high voltage is applied between the drain region 124D and the gate electrode 108 on the assumption that a low voltage is applied between the source region 124S and the gate electrode 108. The source side structure and the drain side structure may be converted based on the circuit's requirement.

FIG. 12B shows the circuit structure wherein two n-channel TFTs are connected to each other in series. The circuit comprises a serial connection of two TFTs connected between a ground potential GND and a supply voltage VDD. A signal A is applied to the gate electrode of the VDD side TFT, and a signal B is applied to the GND side TFT. In such the circuit, it is preferable that the long LDD region 114L is arranged in the drain side area of the VDD side TFT.

FIG. 12C shows a CMOS inverter circuit having a serial connection of n-channel TFT and p-channel TFT connected between a voltage VEE and a voltage VDD. Gate electrodes of both TFTs are connected to an input terminal IN, and interconnection node of the two TFTs is connected to an output terminal OUT. In such the circuit, it is preferable that the long LDD regions 114L are arranged in the source/drain regions which are connected to the output terminal OUT.

FIG. 12D shows a clocked inverter circuit wherein an n-channel TFT and a p-channel TFT are connected in series and are further connected through clocked n-channel TFT and p-channel TFT to a voltage VEE and a voltage VDD. The central CMOS structure is connected to an input terminal IN, and interconnection node of these TFTs in the CMOS structure is connected to an output terminal OUT. Each of the n-channel TFT and p-channel TFT sandwiching the CMOS circuit receives a clock signal.

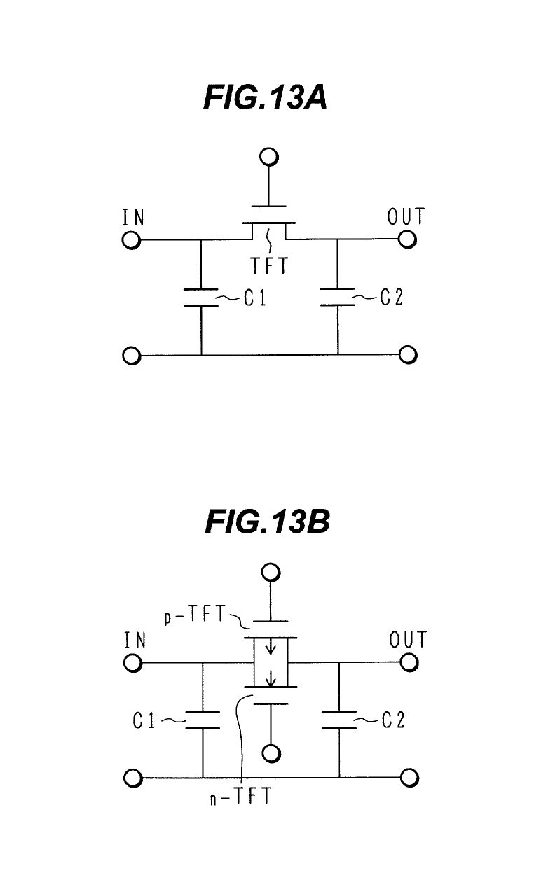

In the same manner as shown in FIG. 12C, it is preferable that the long LDD regions 114L are arranged at interconnection node side in the CMOS circuit. FIGS. 13A and 13B show a sampling circuit using the TFTs described in the above embodiments.

FIG. 13A shows a circuit comprising a pair of input terminals IN which are connected across a sampling capacitor Cl, and a pair of output terminals OUT which are connected across the other sampling capacitor C2. One electrode of the sampling capacitor C1 and that of the other sampling capacitor C2 are connected to each other commonly. The other electrodes of the sampling capacitors C1 and C2 are connected through a TFT as described in the above embodiments. Since a leak current of the TFT described in the above embodiments is very small, excellent retention rate of the sampling signal can be achieved.

FIG. 13B shows the structure of a sampling circuit using a CMOS TFT. In stead of the TFT used in the circuit shown in FIG. 13A, this circuit comprises a switching transistor wherein a p-channel TFT and an n-channel TFT are connected to each other in parallel.

The above described embodiments exemplify a manufacturing method of a top-gate type TFT wherein the ion implantation is carried out while using the gate electrode as a mask. The steps employed in the process of manufacturing the top-gate type TFT, that is: doping the semiconductor layer directory or through only a thin insulation film; forming the LDD regions and heavily doped regions by ion implantation with low acceleration energy; and even laser annealing to activate impurities and recover damages, are also applicable to process of manufacturing a bottom-gate type TFT.

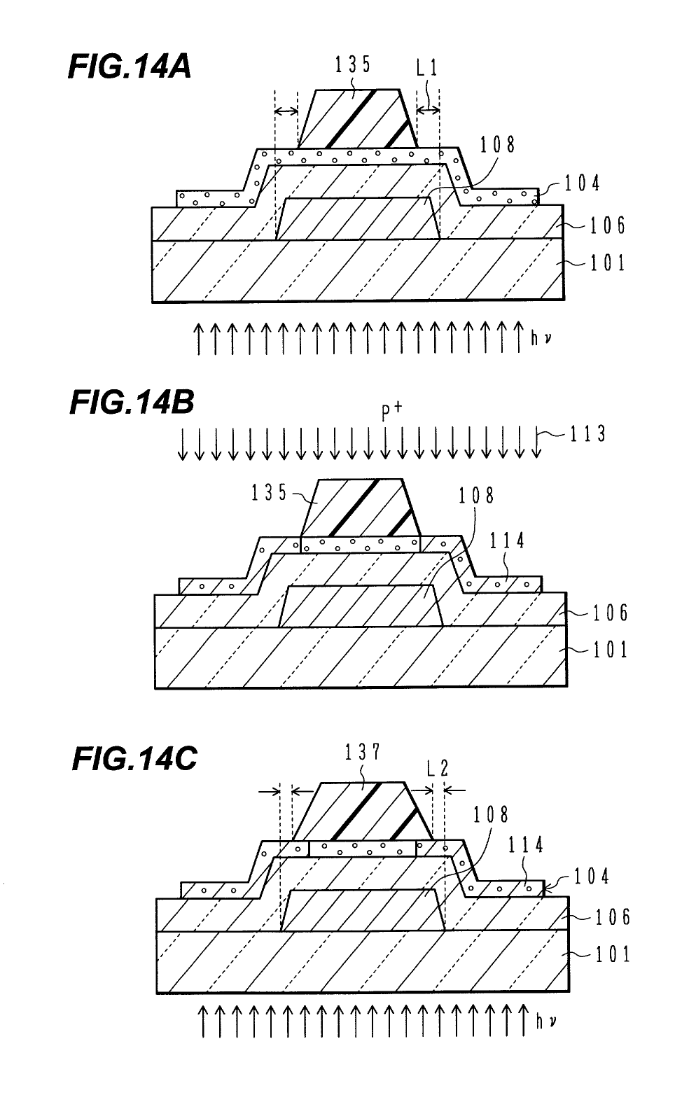

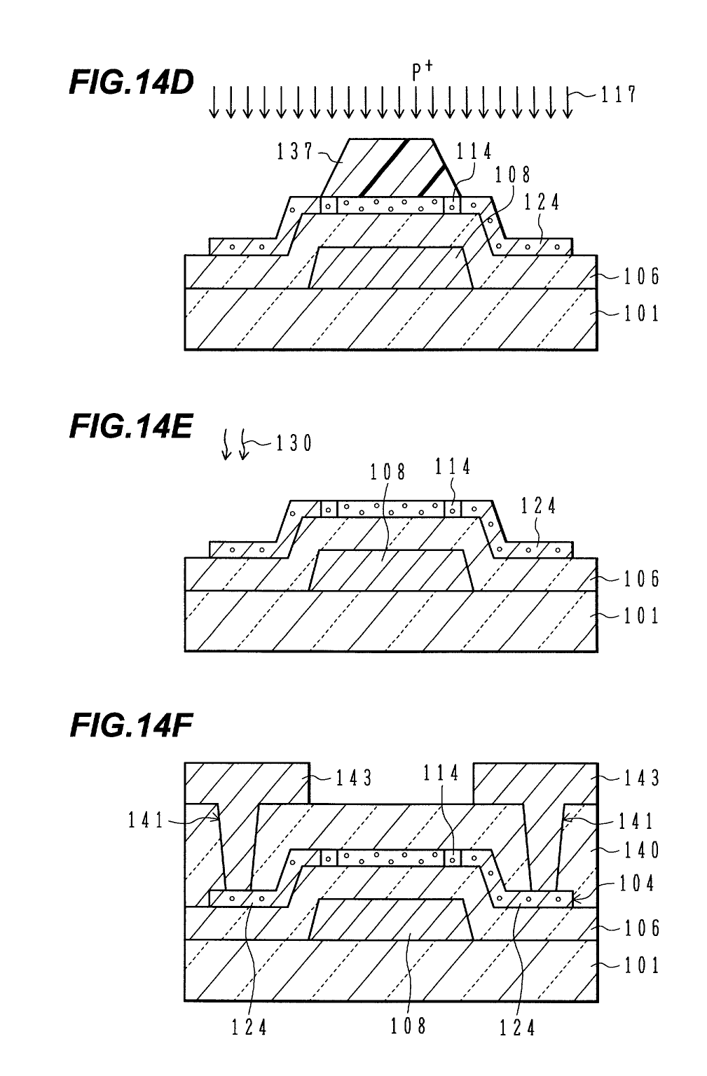

FIGS. 14A to 14F show process of manufacturing a bottom-gate type TFT.

As shown in FIG. 14A, a gate electrode 108 made of Cr or the like is formed on a glass substrate 101, and a gate insulation film 106 of an SiO₂ film or the like is formed so as to cover the gate electrode 108. And a polysilicon layer is formed on the gate insulation film 106, and is patterned to be a semiconductor layer 104.

After applying a resist member to the semiconductor layer 104 so as to cover it, thus applied resist layer is exposed to lights from downward. As a result, the resist layer is exposed while being self aligned so as to be registered with the gate electrode 108. And then, the resist layer is developed to leave an unexposed resist region 135. The length of retardation L1 between an edge of the gate electrode 108 and an edge of the resist pattern 135 is adjustable by changing the exposure degree.

Then, doping of small dose P⁺ ions 113 is carried out with low acceleration energy while using the resist pattern 135 as a mask, as shown in FIG. 14B. For example, the doping of the P⁺ ions 113 whose dose is 5×10¹² cm⁻² is carried out with the acceleration energy of 10 to 30 keV. After the ion implantation, the resist pattern 135 is removed. Thus, LDD regions 114 are formed.

Another resist member is applied to the semiconductor layer 104 so as to cover it, and the resist film is exposed by lights from downward to form a resist pattern 137, as shown in FIG. 14C. Exposure degree is adjusted so that the length of retardation L2 between the edge of the gate electrode 108 and an edge of the resist pattern 137 is smaller than the former retardation L1. That is, the resist pattern 137 becomes wider than the resist pattern 135. Edges of the LDD regions 114 are covered with the resist pattern 137.

Large dose ion implantation is carried out with low acceleration energy while using the resist pattern 137 as a mask, as shown in FIG. 14D. For example, doping of P⁺ ions 117 whose dose is 5×10¹⁴ cm⁻² is carried out with the acceleration energy of 10 to 30 keV. Thus, heavily doped source/drain regions 124 are formed. After the ion implantation, the resist pattern 137 is removed.

Then, a laser beam 130 is irradiated onto the exposed semiconductor layer in which the ions have been implanted, in order to anneal these regions, as shown in FIG. 14E. This annealing process is similar to the aforementioned activation annealing process.

An interlayer insulation film 140 made of SiO₂, polyimide or the like is formed so as to cover the semiconductor layer 104, as shown in FIG. 14F. Contact holes 141 are provided to the interlayer insulation film 140. The source/drain regions 124 are partially exposed through the contact holes 141. An electrode layer 143 is formed, and is pattered to form wiring.

In this embodiment, the required acceleration energy for the ion implantation is also low because the ions are implanted into the semiconductor layer directly. Therefore, the semiconductor layer and the gate insulation film have no significant damage. Moreover, direct irradiation of the laser beam onto the semiconductor layer realizes excellent laser annealing under the same condition.

Even if a thin oxidized film is formed on the semiconductor layer surface, similar effect may be obtained.

In the above described embodiments, two resist patterns, one for the LDD region and the other for the heavily doped region, were formed.

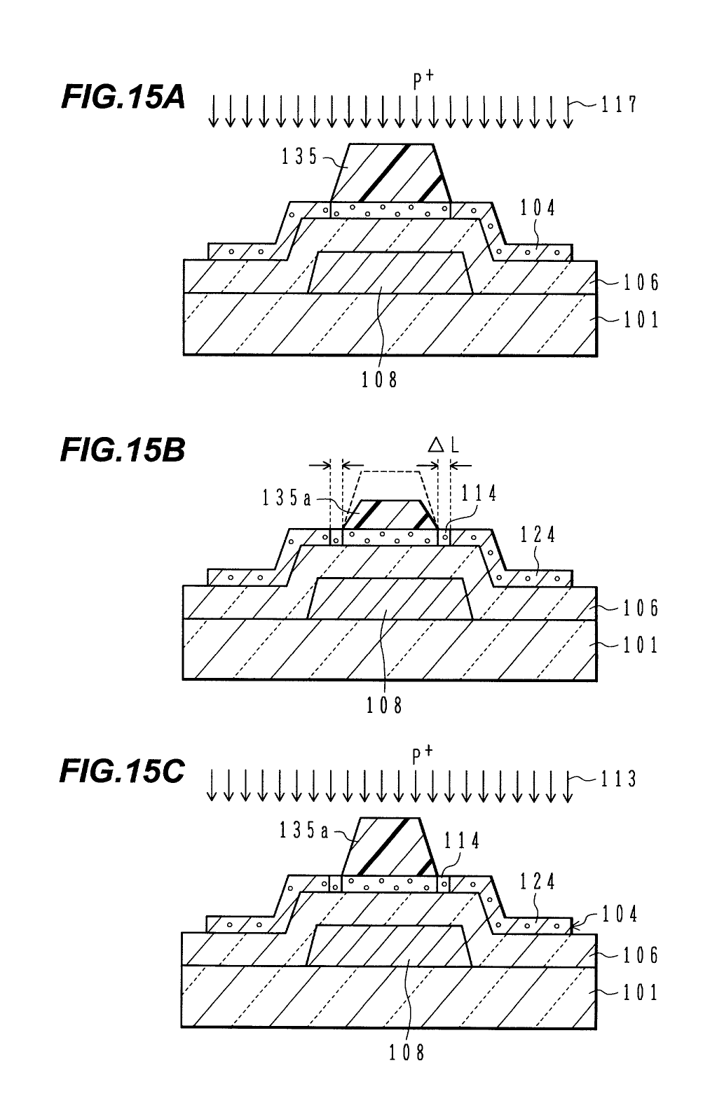

FIGS. 15A to 15C show process of manufacturing a bottom-gate type TFT according to still another embodiment of the present invention.

As shown in FIG. 15A, a gate insulation film 106 covers a gate electrode 108 formed on an insulation substrate 101. A polysilicon layer 104 is formed on the gate insulation film 106. A resist member is applied to the polysilicon layer 104, and is exposed to lights to form a resist pattern 135.

Large dose ion implantation is carried out with low acceleration energy while using the resist pattern 135 as a mask. For example, doping of P⁺ ions 117 whose dose is 5×10¹⁴ cm⁻² is carried out with the acceleration energy of 10 to 30 keV.

The resist pattern 135 is partially ashed as shown in FIG. 15B after the large dose ion doping with the low acceleration energy is finished. The resist pattern 135 shrinks because of the ashing. Thus, the resist pattern 135 is retarded, that is, transformed to a small resist pattern 135a. Because the resist pattern is retarded, regions which have not been implanted with ions are exposed. ΔL denotes the length of the exposed region.

As shown in FIG. 15C, small dose ion implantation is carried out with low acceleration energy while using the transformed resist pattern 135a as a mask. For example, doping of P⁺ ions 113 whose dose is 5×10¹² cm⁻² is carried out with the acceleration energy of 10 to 30 keV. Thus, LDD regions 114 are formed in areas each between the heavily doped region 124 and the resist pattern 135a.

Although the present invention has been explained with reference to the above embodiments, it will be apparent to those skilled in the art that various modifications, combinations, etc. are possible.

What are claimed are:

1. A method of manufacturing thin film transistors comprising the steps of:
(a) forming a plurality of island-shaped semiconductor layers on a substrate having an insulative surface;
(b) implanting dopant into first regions at outsides of a region designated for a channel region in each of said semiconductor layers directly or through a thin insulation film whose thickness is equal to or less than 50 nm by ion implantation to form lightly doped regions; and
(c) implanting dopant into regions at outsides of said first regions in each of said semiconductor layers directly or through said thin insulation film to form heavily doped source/drain regions whose impurity concentration is higher than that of said lightly doped regions.

2. The method of manufacturing the thin film transistors according to claim 1, wherein said ion implanting steps (b) and (c) are carried out using an apparatus for non-mass-analyzed ion implantation which uses an ion source comprising a filament which emits thermal electrons.

3. The method of manufacturing the thin film transistors according to claim 2, wherein said ion implanting steps (b) and (c) are carried out with acceleration energy equal to or less than 30 keV.

4. The method of manufacturing the thin film transistors according to claim 2, wherein said ion implanting steps (b) and (c) are carried out using a hydride of a dopant element as an ion source.

5. The method of manufacturing the thin film transistors according to claim 1, wherein said step (a) comprises the substeps of:
(a-1) depositing an amorphous semiconductor layer on said substrate; and
(a-2) irradiating a layer beam on said amorphous semiconductor layer, to change said amorphous semiconductor layer into a crystalline semiconductor layer.

6. The method of manufacturing the thin film transistors according to claim 3 further comprising the step of;
(d) after said step (c), irradiating a laser beam onto said lightly doped regions and said source/drain regions directly or through said thin insulation film to activate impurities and recover damages caused by the ion implantation.

7. The method of manufacturing the thin film transistors according to claim 4 further comprising the steps, before said steps (b) and (c), of:
(e) forming an insulation layer and an electrode layer, covering said semiconductor layers; and
(f) patterning said electrode layer and said insulation layer to form gate electrodes and gate insulation films on the channel regions so that each of said semiconductor layers is partially exposed at both sides of each of said gate insulation film,
wherein said ion implanting step (b) is carried out while using said patterned gate insulation films and gate electrodes as a mask.

8. The method of manufacturing the thin film transistors according to claim 7, wherein said gate insulation films have a thickness of equal to or greater than 50 nm, and said gate electrodes have a thickness of equal to or greater than 200 nm.

9. The method of manufacturing the thin film transistors according to claim 8, wherein said patterning step (f) patterns edges of each of said gate electrodes retarded from edges of associated one of said gate insulation films.

10. The method of manufacturing the thin film transistors according to claim 7, further comprising, before said step (e) and after said step (f), the step of;
(g) forming a shield on side walls of said gate electrode and said gate insulation film, while covering part of said lightly doped region.

11. The method of manufacturing the thin film transistors according to claim 10, wherein said step (g) comprises the substeps of:
(g-1) depositing a shield layer on said substrate, covering said gate electrode; and
(g-2) anisotropically etching said shield layer to remove the shield layer on flat surfaces, while leaving said shield on the side walls.

12. The method of manufacturing the thin film transistors according to claim 10, further comprising, after said step (c), the step of;
(h) removing said shield.

13. The method of manufacturing the thin film transistors according to claim 7, wherein said ion implanting steps (b) and (c) use hydride of dopant element as ion source and are carried out onto bare surfaces of said semiconductor layers or through natural oxide films of a thickness equal to or less than approximately 5 nm under such conditions that concentration of hydrogen ions passing through said gate insulation films and reaching said semiconductor layers, is equal to or less than 10¹⁷ cm⁻³.

14. The method of manufacturing the thin film transistors according to claim 1, wherein said substrate is a transparent substrate, comprising, before said step (a), the steps of:
(i) forming gate electrodes on said substrate; and
(j) forming a transparent gate insulation film on said substrate covering said gate electrodes.

15. The method of manufacturing the thin film transistors according to claim 14, further comprising, after said step (a) and before said steps (b) and (c), the steps of:
(k) forming a photoresist layer on said substrate, covering said semiconductor layer;
(l) exposing said photoresist layer from a rear surface of said substrate, using said gate electrode as a mask; and
(m) developing said exposed photoresist layer, to form a mask for ion implantation.

16. A method of manufacturing thin film transistors comprising the steps of:
(a) depositing an underlying insulation layer onto a glass substrate;
(b) depositing an amorphous silicon layer onto said underlying insulation layer;
(c) irradiating an eximer laser beam onto said amorphous silicon layer to convert said amorphous silicon layer into a polysilicon layer;
(d) patterning said polysilicon layer to form a plurality of island-shaped polysilicon layers;
(e) forming lamination including a lower insulation layer and an upper conductive layer on said glass substrate, covering said island-shaped polysilicon layers;
(f) forming a first mask on said conductive layer;
(g) patterning said conductive layer and said insulation layer, using said first mask as a mask, to form a gate electrode and a gate insulation film on each of said island-shaped polysilicon layers;
(h) implanting dopant lightly into said polysilicon layers, using said gate electrodes and said gate insulation films as a mask to form lightly doped regions;
(i) forming a second mask on side walls of each of said gate electrodes and gate insulation films, covering each of said polysilicon layers partially;
(j) implanting ions into said polysilicon layers, using said second mask as a mask, to form heavily doped source/drain regions whose impurity concentration is higher than that of said lightly doped regions;
(k) removing said second mask; and
(l) irradiating an eximer laser beam onto said lightly doped regions and said source/drain regions to activate impurities and recover damages caused by the ion implantation.

17. The method of manufacturing the thin film transistors according to claim 16, wherein said ion implanting steps (h) and (j) are carried out with acceleration energy of equal to or less than 30 keV.

18. Thin film transistors comprising:
a substrate having an insulative surface;
a plurality of island-shaped crystalline silicon layers formed on said substrate;
gate insulation films formed at a center of said crystalline silicon layer;
lightly doped regions formed in said crystalline silicon layers outwards from edges of said gate insulation film;
pairs of heavily doped source/drain regions, whose impurity concentration is higher than that of said lightly doped regions, formed in said crystalline silicon layers outwards from edges of said pair of lightly doped regions; and
gate electrodes formed on said gate insulation films, whose edges are retarded from edges of said gate insulation film.

19. The thin film transistors according to claim 18, wherein an area in said crystalline silicon layers under said gate electrode includes hydrogen atoms at a concentration equal to or less than 10¹⁷ cm⁻³.

20. The thin film transistors according to claim 18, wherein said gate insulation films have a thickness of equal to or greater than 50 nm, and said gate electrodes have a thickness of equal to or greater than 200 nm.

21. The thin film transistors according to claim 18, wherein said plurality of island-shaped crystalline silicon layers includes areas for n-channel transistors and areas for p-channel transistors, said lightly doped regions are formed only in the areas for said n-channel transistors.
